(19) United States
(12) Patent Application Publication
(10) Pub. No.: US 2026/0201754 A1
(43) Pub. Date: Jul. 16, 2026

(54) WEAR DATA CLASSIFICATION WITH MACHINE LEARNING FOR WELL TOOLS

(71) Applicant: Taurex Drill Bits, LLC, Norman, OK (US)

(72) Inventors: Dustin LYLES, Norman, OK (US); Warren DYER, Norman, OK (US); Tyler ABLA, Norman, OK (US)

(73) Assignee: Taurex Drill Bits, LLC, Norman, OK (US)

(21) Appl. No.: 19/183,320

(22) Filed: Apr. 18, 2025

Related U.S. Application Data
(63) Continuation-in-part of application No. 18/169,582, filed on Feb. 15, 2023.
Application No. 18/169,582 is a continuation-in-part of application No. 17/698,123, filed on Mar. 18, 2022, now Pat. No. 12,338,686.
Application No. 17/698,123 is a continuation of application No. 17/320,423, filed on May 14, 2021, now Pat. No. 11,301,989.
(60) Provisional application No. 63/024,754, filed on May 14, 2020.
(60) Provisional application No. 63/636,165, filed on Apr. 19, 2024.

(51) Int. Cl. E21B 10/42; E21B 12/02; G06F 18/214; G06F 18/24; G06F 30/10; G06F 30/28; G06T 7/00; G06T 7/11; G06T 7/30; G06T 11/00; G06V 20/64

(52) U.S. Cl. CPC E21B 10/42; E21B 12/02; G06F 18/214; G06F 18/24; G06F 30/10; G06F 30/28; G06T 7/001; G06T 7/11; G06T 7/30; G06T 11/00; G06V 20/647; E21B 2200/20; G06T 2207/20021; G06T 2207/20081; G06T 2207/30164

(57) ABSTRACT

Embodiments of the present disclosure provide systems and methods for analyzing well tools. Methods may include a method for quantifying wear data on a well tool, including scanning a used well tool with one or more scanners and thereby generating a scanned file of the used well tool, the scanners being in communication with a computer system, generating a normalized coordinate format at the computer system, based in part on dimensional information associated with the used well tool, aligning the scanned file with a reference surface of the used well tool using the normalized coordinate format, wherein the reference surface is defined using a set of points within the normalized coordinate format, and is stored on the computer system, and calculating deviation between the scanned file and the reference surface using and thereby determining material removed from the individual wear parts of the used well tool.

### CROSS REFERENCE TO RELATED APPLICATIONS

The present application claims the benefit of, and is a continuation-in-part of U.S. patent application Ser. No. 18/169,582, filed Feb. 15, 2023, which is a continuation-in-part of U.S. patent application Ser. No. 17/698,123, filed Mar. 18, 2022, which is a continuation of U.S. Pat. No. 11,301,989, filed May 14, 2021, which claims priority to U.S. Provisional Patent Appln. No. 63/024,754, filed on May 14, 2020. Additionally, the present application claims priority to U.S. Provisional Patent Appln. No. 63/636,165, filed Apr. 19, 2024.

The above identified applications are hereby incorporated herein by reference in their entireties.

### FIELD OF THE DISCLOSURE

The present disclosure is related to analyzing well tools and, more particularly, to scanning used well tools with three-dimensional or two-dimensional imaging systems and subsequently quantifying wear data.

### BACKGROUND

In the oil and gas industry, several types of well tools are used downhole to perform various wellbore operations. Drill bits, for example, are commonly run downhole two or three (or more) times to drill a wellbore or extend its length. When a drill bit is new, its performance and drilling capability are fairly predictable and generally follow manufacturer specifications. In later stages, however, and due to uncertain operating and formation conditions, the drill bit will gradually wear and degrade into what is commonly referred to as a “dull” bit. Dull bits can slow the rate of wellbore penetration, thus requiring the drilling operator to apply more weight on bit, which, in turn, accelerates drill bit wear. Dull bits also often experience unbalanced side forces, which lead to whirl, vibration, and instability during operation. Consequently, when a drill bit becomes dull, it is commonly removed from operation and either scrapped or refurbished for subsequent use.

Determining whether a bit is scrapped or refurbished is typically based upon internal guidelines established by individual bit companies and experienced personnel within those companies. In addition to making determinations on repairability of dull bits, it is critical to document wear sustained on dull drill bits. The International Association of Drill Contractors (IADC) bit dull grading system was developed to provide a standardized protocol for evaluating drill bits to classify drill bit wear/damage and reason pulled. In the IADC dull grading process, a skilled evaluator visually inspects the dull bit and manually quantifies the observed wear using a standardized eight-field code with associated descriptors. The dull grading process, however, is a time-consuming process that is highly subjective, rarely repeatable, and often inaccurate.

Thus, what is needed is an improved method of determining and quantifying drill bit wear, which can lead to improved bit material selection, design optimization, and performance.

### SUMMARY OF THE DISCLOSURE

Various details of the present disclosure are hereinafter summarized to provide a basic understanding. This summary is not an exhaustive overview of the disclosure and is neither intended to identify certain elements of the disclosure, nor to delineate the scope thereof. Rather, the primary purpose of this summary is to present some concepts of the disclosure in a simplified form prior to the more detailed description that is presented hereinafter.

According to an embodiment consistent with the present disclosure, a method of quantifying wear data on a well tool may include a number of steps. The method may include scanning a used well tool with one or more scanners and thereby generating a scanned file of the used well tool, the scanner being in communication with a computer system. The method may include generating a normalized coordinate format at the computer system, based in part on dimensional information associated with the used well tool. The method may include aligning the scanned file with a reference surface of the used well tool using the normalized coordinate format, wherein the reference surface is defined using a set of points within the normalized coordinate format, and is stored on the computer system. The method may include calculating deviation between the scanned file and the reference surface and thereby determining material removed from the individual wear parts of the used well tool.

According to an embodiment consistent with the present disclosure, a method of classifying wear data on a well tool may be provided. The method may include training, at a machine learning engine, a neural network stored on a computer system to categorize common failure modes sustained by used well tools during operation. Training may include inputting an input dataset including a plurality of known failure mode images. Training may include comparing the input dataset to an output generated using the neural network. Training may include, based on the comparing, adjusting one or more weights of the neural network. The method may include scanning a used well tool with one or more scanners in communication with the computer system and thereby generating a scanned file of the used well tool, the scanned file being aligned with a reference surface based on a normalized coordinate format. The method may include generating one or more failure modes sustained by the used well tool by applying, at the machine learning engine, the neural network to the scanned file.

According to an embodiment consistent with the present disclosure, system may include a number of features. The system may include one or more scanners arrangeable to scan a used well tool. The system may include a computer system in communication with the scanners and including a non-transitory, computer readable medium programmed with computer executable instructions that, when executed by a processor of the computer system, performs the steps of: generating a scanned file of the used well tool based on a signal received from the scanners, the scanned file being aligned with a reference surface based on a normalized coordinate format, generating a normalized coordinate format at the computer system, based in part on dimensional information associated with the used well tool, aligning the scanned file with a reference surface of the used well tool sing the normalized coordinate format, wherein the reference surface is defined using a set of points within the normalized coordinate format, and is stored on the computer system, calculating deviation between the scanned file and the reference surface using and thereby determining material removed from the individual wear parts of the used well tool.

Any combinations of the various embodiments and implementations disclosed herein can be used in a further embodiment, consistent with the disclosure. These and other aspects and features can be appreciated from the following description of certain embodiments presented herein in accordance with the disclosure and the accompanying drawings and claims.

### BRIEF DESCRIPTION OF THE DRAWINGS

The following figures are included to illustrate certain aspects of the present disclosure, and should not be viewed as exclusive embodiments. The subject matter disclosed is capable of considerable modifications, alterations, combinations, and equivalents in form and function, without departing from the scope of this disclosure.

FIG. 1 is an isometric view of an example well tool that may incorporate the principles of the present disclosure.

FIG. 2 is a schematic diagram of an example scanning system that may incorporate the principles of the present disclosure.

FIG. 3 is a process flow diagram of an example method of determining and quantifying wear data on a well tool, according to one or more embodiments.

FIG. 4 depicts example solid model and scanned file outputs to which manual point pair alignment has been undertaken, according to one or more embodiments.

FIGS. 5A and 5B depict example digital features applied to specific wear parts of the drill bit of FIG. 1, according to one or more embodiments.

FIGS. 6A and 6B depict enlarged images of an example cutting element demonstrating area point cloud measurements, according to one or more embodiments.

FIGS. 7A-7D are example wear data reports that may be generated using an auto-generate report programming instruction, according to one or more embodiments.

FIG. 8 is an enlarged scanned view of a worn cutter seated within a corresponding cutter pocket, according to one or more embodiments.

FIG. 9A is an isometric view of an example cutting element after having sustained failure damage and depicting an extracted surface feature created based on the surface of the failure plane.

FIG. 9B is a graphical representation of missing portions of the cutting element of FIG. 9A.

FIG. 10 depicts an example of computational fluid dynamics flow lines across a drill bit being correlated to cutting element wear, according to one or more embodiments.

FIG. 11 is a schematic diagram of the computer system of FIG. 2.

FIG. 12 is a diagram of a well tool wear classification system with machine learning, according to one or more embodiments.

FIG. 13 is a process flow diagram of a method for classifying well tools, according to one or more embodiments.

FIG. 14 is a diagram of a machine learning engine, according to one or more embodiments.

FIG. 15 shows images of different types of cutting element failures.

FIGS. 16A, 16B and 16C show examples of automated radial position reporting for different cutting elements.

FIG. 17 is a schematic diagram of another example scanning system that may incorporate the principles of the present disclosure.

FIG. 18 shows two example images output by a wear classifier tool that show locations of cutting elements according to an embodiment.

FIG. 19 shows four example images of cutting elements for use in a training set.

FIG. 20 is a graph illustrating results of an example case study for a new cutter drill bit and incumbent cutter drill bit analyzed by a wear classifier tool according to an embodiment.

FIG. 21 shows images of different types of substrate damage that are classified and determined by a wear classification tool in a further embodiment.

FIG. 22 depicts example coordinate elements corresponding to discrete wear parts of the well tool of FIG. 1, according to one or more embodiments.

FIG. 23 depicts example data sources for a normalized coordinate system implemented in the computer system of FIG. 2.

FIG. 24 is a process flow diagram of an example method of determining and quantifying wear data on a well tool, according to one or more embodiments.

FIG. 25 is a schematic diagram of an example scanning system that may incorporate the principles of the present disclosure.

FIGS. 26A and 26B are schematic front and plan views of another example scanning system in accordance with the principles of the present disclosure.

### DETAILED DESCRIPTION

The present disclosure is related to analyzing well tools and, more particularly, to scanning used well tools with three-dimensional or two-dimensional imaging systems and subsequently quantifying wear data.

Embodiments of the present disclosure describe methods of analyzing well tools to determine and quantify wear data. According to methods disclosed herein, a used well tool is scanned and the resulting scanned file is aligned with a solid model (e.g., CAD model) of the well tool in its as-designed state using a normalized coordinate system. The scanned model is then compared to the solid model. Material loss can then be measured directly for analysis by subtracting the scanned parts from the corresponding solid model parts. One issue with conventional scanning of well tools is that the scan data is commonly represented as a single surface geometry that lacks any distinction between individual, discrete components of the well tool. Because the individual components are not discrete 3D solids in conventional scanning techniques, they cannot be easily measured.

Assemblies made up of various parts subject to wear are of interest in defining the amount of wear experienced during operation of the assembly. The presently described methods facilitate measurement of discrete volumetric and/or area wear of components and parts of well tools. The methods disclosed herein provide improved consistency, granularity (i.e., characterization), and accuracy of wear data as feedback for application specific well tool selection, design optimization, and material selection. In some cases, formation characteristics can be correlated to wear identified on well tool cutting elements, thus enabling indexing of formation abrasion, thermal and/or impact severity and probability.

Moreover, the wear or wear rate of specific materials in the well tools can be tracked over time to ensure there is no drifting of performance due to changes in materials and/or manufacturing. Wear and wear rate can also be tracked to better understand variations in lithology and/or drilling parameters of subterranean formations. Furthermore, the methods described herein may help enhance a manufacturer's ability to perform economic analysis and make material selections for well tools based on a rate of return from a performance perspective. Thus, the methods discussed herein provide quick, reliable, and objective feedback to manufacturers, operators, and tool companies to aid in optimization of drilling efficiency and economics.

Moreover, the wear or wear rate of specific materials in the well tools can be tracked over time to ensure there is no drifting of performance due to changes in materials and/or manufacturing. Wear and wear rate can also be tracked to better understand variations in lithology and/or drilling parameters of subterranean formations. Furthermore, the methods described herein may help enhance a manufacturer's ability to perform economic analysis and make material selections for well tools based on a rate of return from a performance perspective. Thus, the methods discussed herein provide quick and reliable feedback to manufacturers, operators, and tool companies to aid in optimization of drilling efficiency and economics.

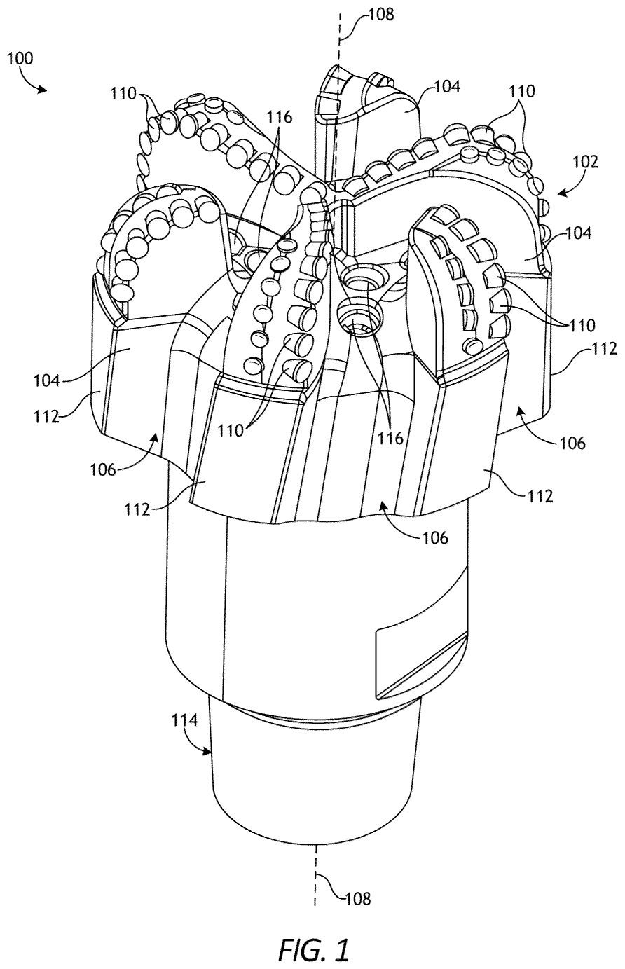

FIG. 1 is an isometric view of an example drill bit 100 that may incorporate the principles of the present disclosure. In the illustrated embodiment, the drill bit 100 comprises a rotary drill bit, but the principles of the present disclosure are equally applicable to other well tools commonly used in the oil and gas industry and corresponding to a wide variety of oilfield equipment (both surface and subsurface), well drilling equipment, well drilling tools, well completion equipment, well completion tools, well service tools, well service equipment, and/or associated components. Other examples of well tools that can be used in accordance with the principles described herein include, but are not limited to, bit bodies associated with rotary drill bits, fixed cutter drill bits (e.g., PDC bits), drill string stabilizers, roller cone drill bits, cones for roller cone drill bits, rotary steering tools (e.g., directional tools), logging while drilling tools, measurement while drilling tools, side wall coring tools, underreamers, fishing spears, washover tools, whipstocks, production packer components, float equipment, casing shoes (e.g., a casing shoe with cutting structures), well screens, gas lift mandrels, downhole tractors, tool joints, rotors, stator and/or housings for downhole motors, blades and/or housings for downhole turbines, latches for downhole tools, and other downhole tools associated with drilling and completing a wellbore.

In the present discussion, the drill bit 100 will be described with reference to the rotary drill bit depicted in FIG. 1. The term “rotary drill bit” refers to various types of fixed cutter drill bits, drag bits, matrix drill bits, steel body drill bits, roller cone drill bits, rotary cone drill bits, and rock bits operable to form a wellbore. As will be appreciated, rotary drill bits and associated components incorporating the teachings of the present disclosure may have many different designs, configurations, and/or dimensions.

As illustrated, the drill bit 100 includes a generally cylindrical bit body 102 that provides or otherwise defines one or more drill bit blades 104 separated by junk slots 106. The blades 104 may be provided in a wide variety of configurations including, but not limited to, substantially arched, helical, spiraling, tapered, converging, diverging, symmetrical, asymmetrical, or any combination thereof. In the illustrated embodiment, some of the blades 104 extend to a centerline 108 of the bit body 102 and may be referred to as “primary” blades, while other blades 104, referred to as “secondary” blades, do not extend to the centerline 108 and operate to “follow” the primary blades 104 during operation.

The bit body 102 can be formed integrally with the blades 104, such as being milled out of a steel blank. Alternatively, the blades 104 can be welded to the bit body 102. In other embodiments, the bit body 102 and the blades 104 may be formed of a matrix material (e.g., tungsten carbide matrix with an alloy binder) sintered and/or cast in a mold of a desired shape, with the blades 104 also being integrally formed of the matrix with the bit body 102.

The drill bit 100 further includes a plurality of cutting elements 110 (alternately referred to as “cutters”) fixed to the blades 104. In some cases, some of the cutting elements 110 may be mounted at the leading face of some or all of the blades 104. Each cutting element 110 may be received within and bonded to a dedicated cutter pocket machined or cast into the bit body 102 at the corresponding blade 104. One or more of the cutting elements 110 may include a cutting table or face bonded to a substrate secured within a corresponding cutter pocket. The cutting table may be made of a variety of hard or ultra-hard materials such as, but not limited to, polycrystalline diamond (PCD), sintered tungsten carbide, thermally stable polycrystalline (TSP), polycrystalline boron nitride, cubic boron nitride, natural or synthetic diamond, hardened steel, or any combination thereof. The substrate may also be made of a hard material, such as tungsten carbide or a ceramic. In other embodiments, however, one or more of the cutting elements 110 may not include a cutting table. In such embodiments, the cutting elements 110 may comprise sintered tungsten carbide inserts without a cutting table and bonded to corresponding cutter pockets. The cutting elements 110 may be bonded to the corresponding blade 104 such that they are fixed or alternately allowed to rotate.

The cutting elements 110 may comprise any suitable cutter designed to cut, gouge, and/or scrape into underlying rock formations as the bit body 102 rotates during downhole operation. The cutting elements 110 can include primary cutting elements, back-up cutting elements, secondary cutting elements, or any combination thereof. In some applications, other types of cutting elements may be fixed to various portions of the primary or secondary blades 104. Such cutting elements can include, but are not limited to, cutters, compacts (e.g., polycrystalline diamond compacts or “PDC” ), buttons, inserts, and gage cutters suitable for use with a wide variety of drill bits. In some cases, the blades 104 may also include one or more depth of cut controllers (DOCCs) configured to control the depth of cut of the cutting elements 110. Various features may also be affixed to the blades 104 to mitigate vibration.

Moreover, the drill bit 100 may further include one or more gauge pads 112 provided on outer radial portions of the blades 104 to contact radially adjacent portions of the drilled wellbore. The gauge pads 112 operate to provide added stability and protection to gauge cutting elements (if any) while maintaining a predetermined diameter of the drilled wellbore. The gauge pads 112 may also contain one or more cutting elements in order to enhance the ability of the well tool to maintain a properly gauged well bore.

The drill bit 100 further includes a pin 114 that defines American Petroleum Institute (API) drill pipe threads used to releasably engage the drill bit 100 with drill pipe or a bottom-hole assembly (BHA) whereby the drill bit 100 may be rotated relative to the centerline 108. In example operation, as the drill bit 100 advances into the earth, a drilling fluid (e.g., water, drilling mud, etc.) is communicated to one or more nozzles 116 provided in the bit body 102 to cool and lubricate the drill bit 100. The drilling fluid is discharged from the nozzles 116 and into the junk slots 106, and a mixture of drilling fluid, formation cuttings, and other downhole debris flow through the junk slots 106 to be returned to the well surface via the annulus of the drilled wellbore.

Operation of the drill bit 100 in downhole environments inevitably causes wear and tear on the drill bit 100, which gradually decreases its efficiency and effectiveness. Eventually the decreased drilling efficiency of the drill bit 100 outweighs the drilling interests and the drill bit 100 must be returned to the surface and replaced or refurbished.

As indicated above, dull bits are either scrapped or refurbished for subsequent use and, in some cases, this determination is reached by a skilled evaluator. Because the dull grading process is time-consuming, highly subjective, and often inaccurate, other wear analysis techniques have been developed to provide more efficient means of wear data quantification. For example, worn well tools, such as drill bits, can be digitally scanned to obtain and process three-dimensional (3D) images of the worn well tools that help manufacturers determine whether a worn well tool should be scrapped or refurbished. Moreover, metrology software has been developed to calculate wear by comparing separate models, but conventional scanning techniques quantify wear (i.e., deviation) for a body as a whole, and are not designed to distinguish wear/deviation for separate, distinct parts or components within one scanned image. More specifically, conventional methods of scanning well tools to determine material loss (volumetric and/or area) typically generate scan data represented as a single, monolithic surface geometry that lacks any distinction between the individual, discrete components (parts) of the well tool. Because the individual components are not discrete 3D solids, they cannot be measured independently but only as part of the whole. It is believed that no solution has previously been disclosed that automates material loss/wear calculations for individual, discrete wear parts or components of a well tool.

According to the present disclosure, when evaluating the wear state and characteristics of a well tool, such as the drill bit 100, wear is linked and/or correlated to specific regions or “wear parts” of the well tool. As used herein, the term “wear parts” refers to parts, components, or regions of a well tool that have a higher susceptibility to wear and tear during operation as compared to other parts, components, or regions of the well tool. Wear parts on the drill bit 100, for example, include at least the blades 104, the cutting elements 110, and the gauge pads 112 due to the significant variation of forces applied to these individual regions across the bit profile. In some embodiments, wear parts can also include depth of cut controllers (DOCCs), if present. Additionally, these separate regions of the bit profile experience various forms and severity of impact loading/instability, perform varying degrees of work, travel at varying speeds, and travel highly variable distances.

The methods described herein automate the process of scanning a worn well tool to identify wear parts. In some embodiments, the process may include selecting wear parts of interest on a three dimensional (3D) solid model of the well tool (e.g., a model generated by means of computer-aided design (CAD) software, a mesh derived from a CAD file, a user-defined solid model, a polygon file format (PLY)), applying a CAD, a mesh, 3D reference object, a user-defined object, or the like with normalized coordinates generated using various methods (e.g., derivation from the solid model, user selected in 3D space, or through machine learning techniques) to the solid model and/or the scanned model, aligning the solid and scanned models of the well tool, and calculating the deviation (wear) between the scanned part and the solid model part, thus providing a user (e.g., an operator, a tool company, etc.) with the material loss (volumetric and/or area) at the wear parts of interest. In some embodiments, the process may include identifying wear parts of interest on a three dimensional (3D) set of scanned images of the well tool, applying a reference surface with normalized coordinates generated using various methods (e.g., derivation from the solid model, user selected in 3D space, or through machine learning techniques) to the scanned images, aligning the reference plane and scanned images of the well tool, and calculating the deviation (wear) between the scanned part and the solid model part, thus providing a user (e.g., an operator, a tool company, etc.) with the material loss (volumetric and/or area) at the wear parts of interest. As will be appreciated, the methods described herein may be advantageous over the time-consuming and subjective manual process of analyzing dull drill bits. Whereas manually analyzing a dull drill bit can require several hours of manual labor, the methods disclosed herein can be accomplished in just minutes.

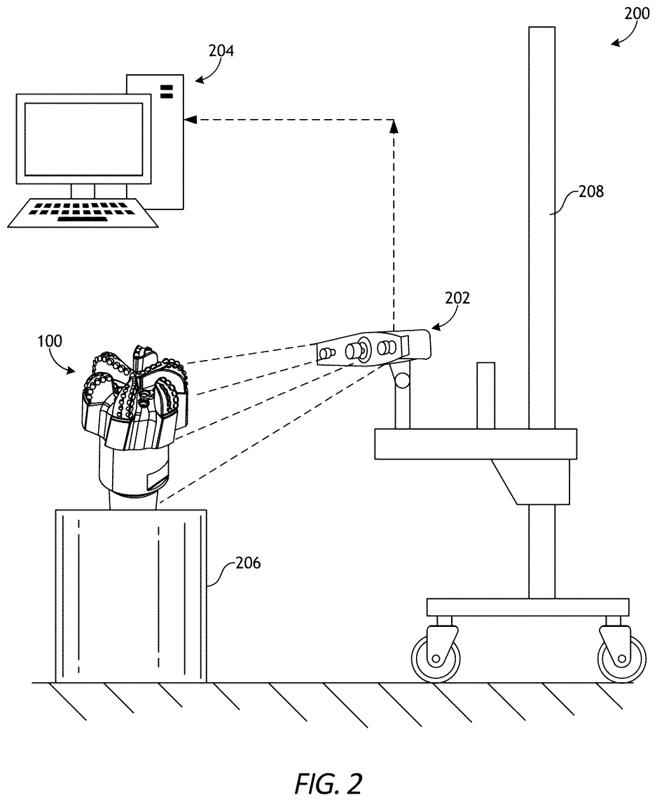

FIG. 2 is a schematic diagram of an example scanning system 200 that may incorporate the principles of the present disclosure. The scanning system 200 (hereafter “the system 200”) may be configured to scan a well tool, such as the drill bit 100. As illustrated, the scanning system 200 includes a scanner 202 and a computer system 204 in communication with the scanner 202. In some embodiments, the computer system 204 may include two or more computers (e.g., multi-pc workflow) networked together or otherwise capable of communicating one with the other. Having more than one computer may be advantageous in increasing capacity (e.g., maximizing number of well tools scanned without delay due to inspection) while creating real-time/simultaneous inspections upon completion of a scan. In such embodiments, for example, the computer system 204 may include a scanning computer separate from an inspection computer, among other computer devices.

The scanner 202 may be positioned to obtain scanned Images of the drill bit 100, which may be positioned on a stand 206. In some embodiments, the scanner 202 may be designed to obtain three-dimensional (3D) images of the drill bit 100 and may thus comprise a type of 3D scanner or 3D scanning system. For purposes of this disclosure, the term “3D scanner” or “3D scanning system” refers to any assembly by which distance data may be collected or calculated and reconstructed to extrapolate the shape and/or texture of an object (e.g., a well tool). Such assemblies may refer to any kind of 3D scanning system, including contact or non-contact 3D scanners, such as a time-of-flight 3D laser scanner, a triangulation 3D scanner, a structured light 3D scanner, an optical 3D scanner, stereoscopic scanners, general photography devices, or any combination thereof. Further, in one or more embodiments, the 3D scanning system may be an internal component of an electronic device or a separate external component connected to an electronic device operable at will by a user.

In other embodiments, however, the scanner 202 may be designed to obtain high-resolution two-dimensional (2D) images of the drill bit 100, without departing from the scope of the disclosure. In such embodiments, the scanner 202 may comprise a high-resolution camera or the like capable of obtaining high-resolution 2D photographic (still) images and/or video. Moreover, in such embodiments, the computer system 204 may be programmed or otherwise configured to implement photogrammetry techniques to gather measurements and data about the well tool by analyzing the change in position from two or more different images. Accordingly, the principles of the present disclosure are equally applicable to 2D scanning operations.

In other embodiments, a second bank of cameras may be included at scanning system 220 and may be configured or otherwise arranged to capture ultra-high-resolution images of specific wear parts of interest.

In some embodiments, the scanner 202 may be mounted to a support assembly 208 capable of moving the scanner 202 about the drill bit 100 to capture scanned images (3D or 2D) of all exterior portions of the drill bit 100. The support assembly 208 may include, for example, one or more robotic arms and/or lifts that may help maneuver and position the scanner 202 at all required angles and locations relative to the drill bit 100. In some embodiments, the support assembly 208 may be automated, but may alternatively be manually operated. In some embodiments, the scanner 202 may remain stationary and the stand 206 may alternatively be rotatable and/or movable up and down to help enable adequate scanning of the drill bit 100. In yet other embodiments, the scanner 202 may comprise a hand-held scanning system and a user or operator may hold the scanner 202 and walk around the periphery of the drill bit 100 while digitally “painting” the drill bit 100 with the scanner 202 to obtain the necessary scanned images (3D or 2D).

In some embodiments, the drill bit 100 may be prepared for scanning, such as by applying reflective markers to assist in stitching the 3D scan together, applying matting spray to remove reflective glare, and the like. The scanner 202 may be designed to operate with an accuracy of approximately 0.0005-0.003 inches or better.

The scanner 202 may communicate with the computer system 204 via any known wired or wireless means. In at least one embodiment, the computer system 204 may comprise one component of a larger computer network. The computer system 204 may include a processor and a non-transitory, computer readable medium (i.e., a memory) programmed with computer-executable instructions that, when executed by the processor, perform the methods described herein. More particularly, the computer system 204 may have 3D modeling and metrology software stored thereon, which may include instructions to receive and process images captured by the scanner 202 and generate a 3D image of the drill bit 100 based on the captured images. For example, computer system 204 may be programmed or otherwise configured to implement photogrammetry techniques to build a textured or colored 3D model of a well tool drill bit 100.

The 3D image of the drill bit 100 may comprise a scanned “mesh” file (e.g., .stl, point cloud, IGES, STEP, etc.) comprising a complex polygon mesh structure corresponding to the scanned dimensions and configurations of the drill bit 100 as obtained by the scanner 202. As described in more detail below, the scanned file of the drill bit 100 may be compared against a solid model (e.g., a computer-aided design or CAD solid model) file of the drill bit 100 corresponding to the original manufacturer specifications for the drill bit 100. The scanned file may be spatially aligned with the corresponding solid model file and any deviation between individual scanned parts (regions) and the corresponding solid model parts may be indicative of how much wear the drill bit 100 experienced during operation. Such comparisons may be used to quantify, often in a digital format, specific amounts of abrasion, erosion, and/or wear of associated blades 104 (FIG. 1), cutting elements 110 (FIG. 1), and/or gauge pads 112 (FIG. 1), for example.

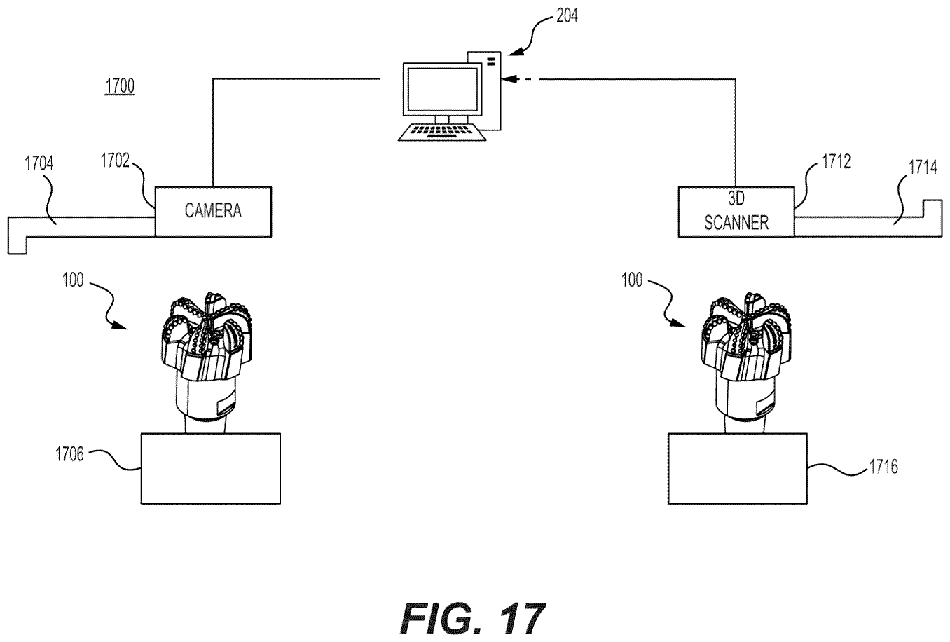

FIG. 17 is a schematic diagram of another example scanning system 1700 that may incorporate the principles of the present disclosure. Scanning system 1700 includes a 2D scanner (such as camera 1702) and a 3D scanner 1712. Camera 1702 can be positioned relative to a drill bit 100 to capture images (e.g., 2D images) of drill bit wear during a scanning operation as described above with respect to FIG. 2. Drill bit 100 may be positioned on a stand 1706. A robotic arm 1704 may be used to move camera 1702 relative to the drill bit 100 and stand 1706. Computer system 204 may be coupled to camera 1702 and robotic arm 1704 to control scanning of drill bit 100 and capture of images by camera 1702. Camera 1702 is illustrative and can be a digital camera, such as, an area image sensor, a line image sensor moved over an area, or other type of 2D scanner.

3D scanner 1712 can be positioned relative to a drill bit 100 to capture images of drill bit wear and distance data (3D images) during a scanning operation as described above with respect to FIG. 2. Drill bit 100 may be positioned on a stand 1716. A robotic arm 1714 may be used to move 3D scanner 1712 relative to the drill bit 100 and stand 1716. Computer system 204 may be coupled to 3D scanner 1712 and robotic arm 1714 to control scanning of drill bit 100 and capture of images and distance data by 3D scanner 1712.

In one embodiment, system 1700 performs 2D scanning and 3D scanning in series on multiple drill bits 100. A first drill bit 100 is scanned by camera 1702 to capture 2D images. Afterwards, drill bit 100 is scanned by 3D scanner 1712 to capture 3D images, while a second drill bit is scanned by camera 1702. This process can be repeated to scan multiple drill bits for wear. Captured 2D images and 3D images are stored in a database or other memory coupled to computer system 204. Computer system 204 can then process the captured 2D images and 3D images and distance data to determine and classify wear, and/or to predict repair or replace with machine learning as described further below.

In one embodiment, captured 2D images represent images of a drill bit 100 taken from different camera positions in a scan. This can include images of blades, cutting elements, bit body, shank, or pin taken from different camera positions and can be tied to a work order and used to store generate reports or other wear analysis. Captured 3D images can be used as input data for a machine learning engine to determine and classify wear, and/or to predict repair or replace with machine learning, such as, deep learning using one or more neural networks.

In one embodiment the 2D scanning by a camera and subsequent failure mode classification by a trained ML model operates independently of the 3D scanning, whereby the trained ML model only classifies failure modes while the 3D model and automated metrology inspection process quantifies the material loss (wear).

In another embodiment the output data from the 2D and 3D processes are compared to one another to improve the accuracy of the ML model and wear quantification and/or failure mode and produce a secondary/resulting, optimized output data. This comparison can improve accuracy. In some cases, there can be inherent inaccuracies in both 2D and 3D scanning processes so comparing the two results can improve accuracy of each. For example, a resolution of a 3D mesh model may have some distortion on the edge of cutting elements that result in biasing of the diamond area removed calculation, and thereby calculating missing diamond when in fact the cutter is fully intact. The high resolution 2D image processed through the ML model would determine there is no wear on the cutter and thus the wear calculation from the 3D model in the metrology inspection could be corrected, producing more accurate measurement.

Furthermore, a trained ML model may be used in the well classifier tool to make a determination on whether a cutting element should be replaced or if it can be rotated in the pocket to expose a new, unworn portion of the cutting element. For example, one or more cutting elements may be determined by the well classifier tool to be in need of rotation in which case the well tool is rotated to expose unused portions of the cutting elements such as those at the circumference of the well tool. The well classifier tool may evaluate wear or damage based on whether a threshold or other metric is exceeded which requires rotation, or if rotation is unacceptable to correct the classified wear then replacement.

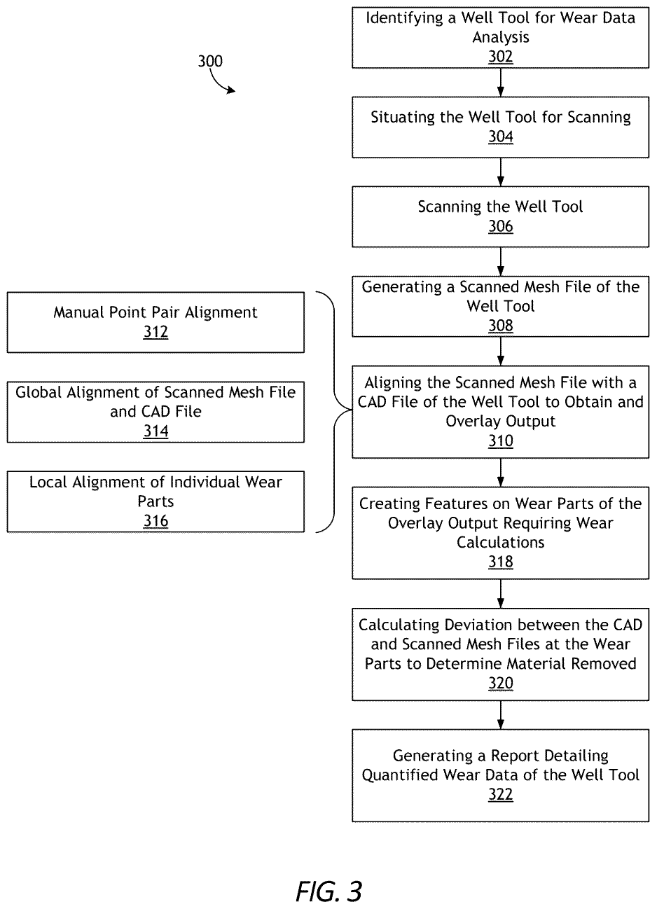

FIG. 3 is a process flow diagram of an example method 300 of determining and quantifying wear data on a well tool, according to one or more embodiments. The method 300 will be discussed with respect to determining and quantifying wear data of the drill bit 100 of FIGS. 1-2, but it will be appreciated that the method 300 may alternatively be used to determine and quantify wear data of any of the well tools or associated components mentioned herein. Moreover, the method 300 may also incorporate and use the scanner 202 (FIG. 2) and the computer system 204 (FIG. 2) described herein to help determine and quantify the wear data.

As illustrated, the method 300 may first include identifying a well tool for wear data analysis, as at step 302. The well tool must be properly identified in order to be able to run the software programming instructions that facilitate automated wear data quantification. In this step, the dull drill bit 100 (or any other well tool mentioned herein) may be identified by the computer system 204 (FIG. 2) based on original design and preparation files used to manufacture the drill bit 100. The design and preparation files can include, but are not limited to, solid models (e.g., CAD files), object-like files, machine learning files generated based on object-like files, and data files (e.g., comma separated variable or “CSV” files, JSON files, YAML Ain't Markup Language (YAML) files, Tom's Obvious Minimal Language (TOML) files) corresponding to the drill bit 100, and may be prepared based on tool features such as part number, outer diameter, cutter size, blade count, etc. The design and preparation files may also include corresponding metadata. In at least one embodiment, the data file could be programmatically generated based on the embedded parts and details provide in the solid model file. More specifically, an operator may be able to merely input a part number or the like and the computer system 204 may be configured to pull the necessary data file information from the solid model file. In such embodiments, the information for the data file may be embedded within the solid model file or otherwise within the bit manufacturer's bit design database.

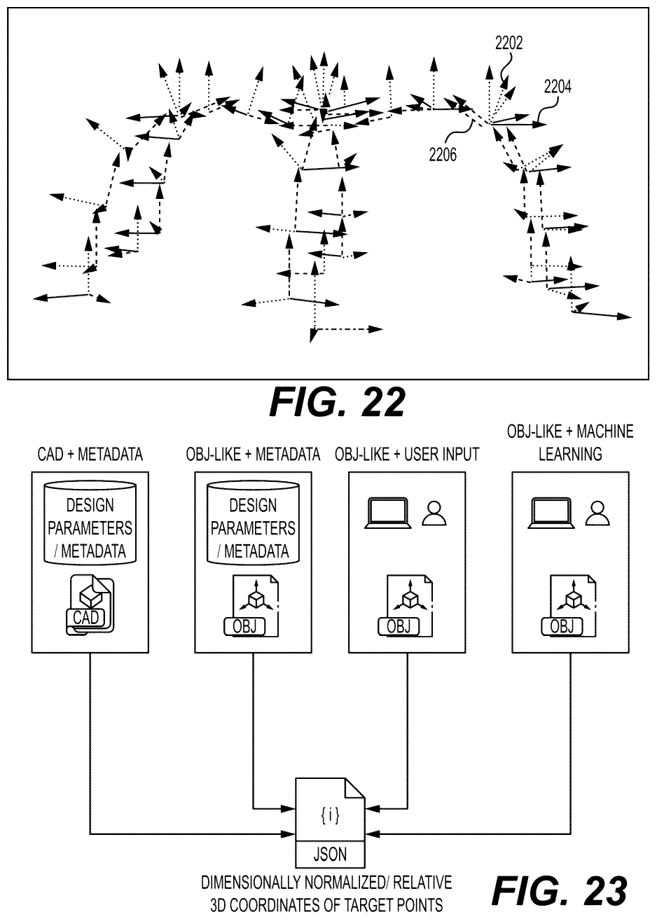

The design and preparation files can include coordinate information. In at least one embodiment, coordinate information may be stored as Cartesian coordinate values (e.g., x, y, z) and Euler angle values (e.g., Rₓ, R_{y}, R_{z}), and may correspond to individual (discrete) wear parts. FIG. 22 depicts example coordinate elements that may correspond to discrete wear parts of the drill bit 100 of FIG. 1, for example. Element 2202 corresponds to an x value and an Rₓ value that may be identified for each discrete wear part. Element 2204 corresponds to an y value and an R_{y} value that may be identified for each discrete wear part. Element 2206 corresponds to an z value and an R_{z} value that may be identified for each discrete wear part. In at least one embodiment, each component of a discrete wear part may be identified via machine learning segmentation. Machine learning segmentation may be performed via machine learning engine 1230, and may include training machine learning engine 1230 to partition images into meaningful segments or regions based on learned patterns and features. This technique involves using labeled training data to teach the machine learning model how to identify and classify different parts of an image, enabling it to accurately segment new images into distinct areas for further analysis or processing

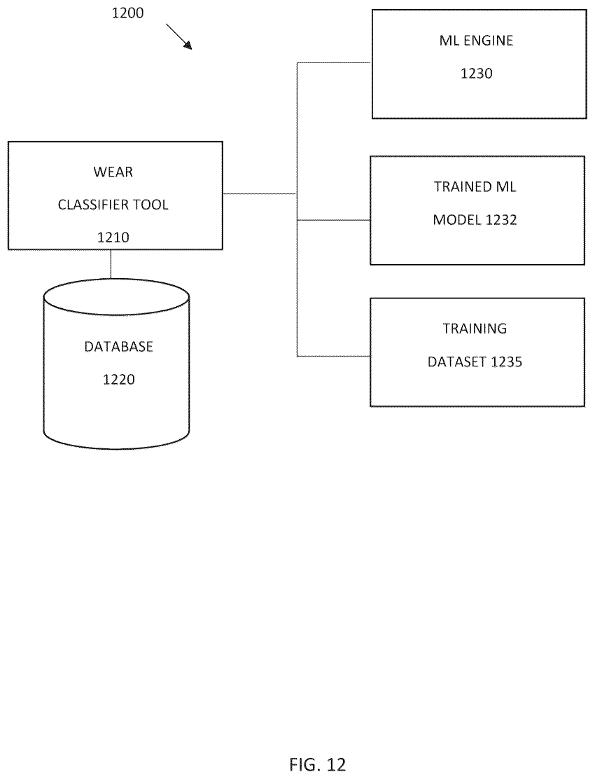

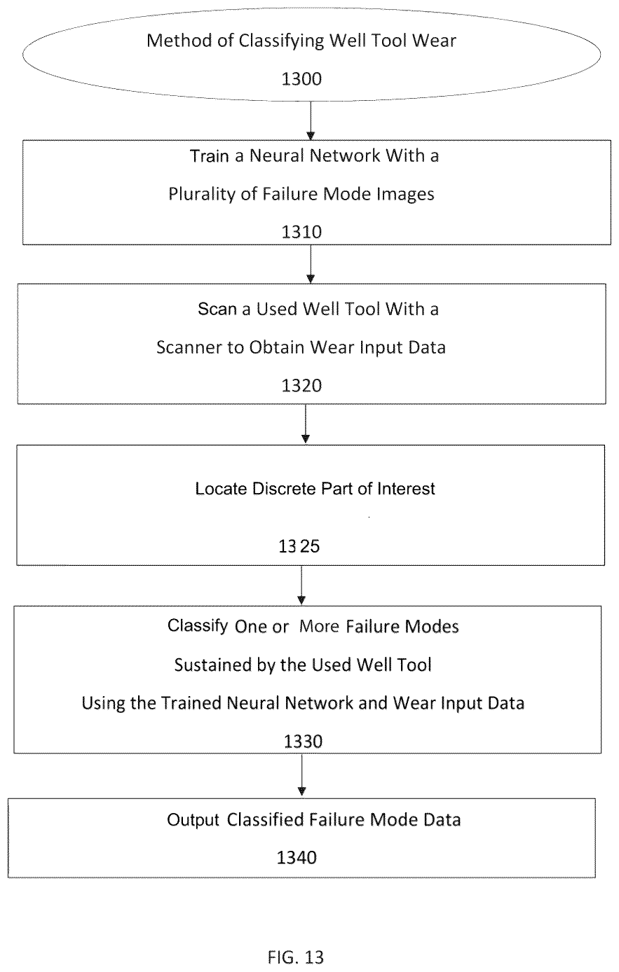

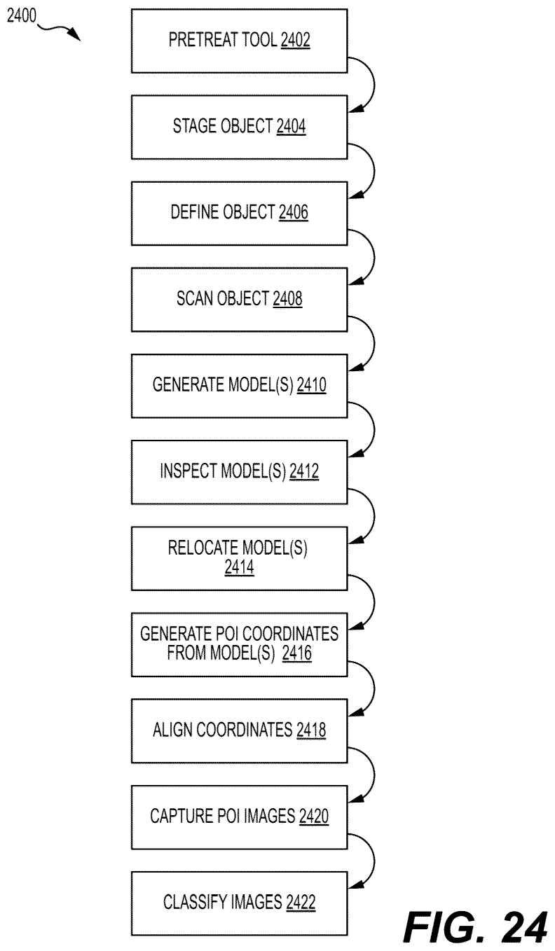

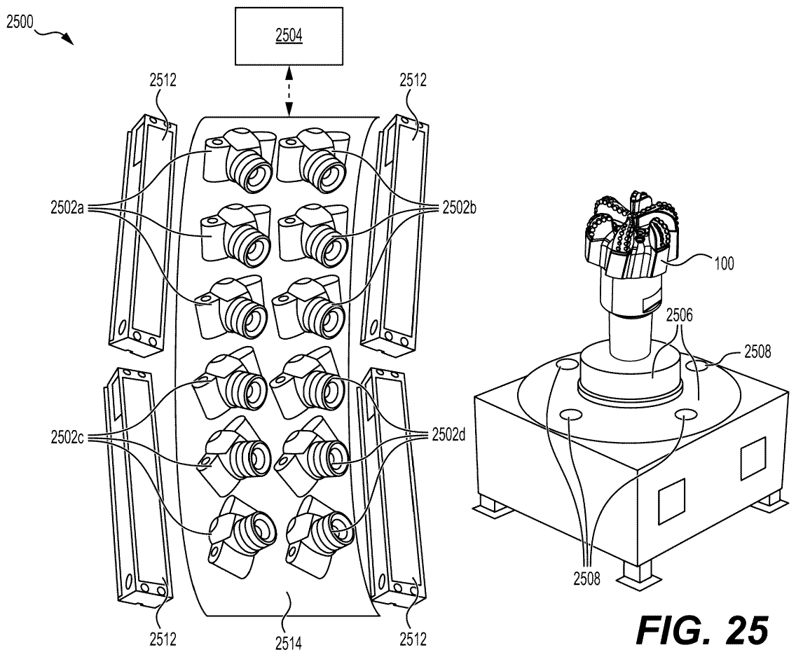

FIG. 23 depicts a schematic diagram of potential data sources for a normalized coordinate system that may be applied to design and preparation files. Accordingly, the normalized coordinate system may be implemented in at least computer system 202 or scanning system 2500 (see FIG. 25). As shown in FIG. 23, the design and preparation files having normalized coordinate information may include at least one of CAD data and metadata, OBJ-like data and metadata, OBJ-like data and corresponding user input, OBJ-like data generated from machine learning techniques, and output information generated from machine learning techniques. The machine learning techniques may include at least one of supervised learning techniques, unsupervised learning techniques, semi-supervised learning techniques, and reinforcement learning techniques. For example, the machine learning techniques may include any portion of the machine learning techniques described with respect to at least FIGS. 12 and 13. The design and preparation files may be derived from any data acquired according to embodiments described in the present disclosure, including method 300 of FIG. 3, method 1300 of FIG. 13, and method 2400 of FIG. 24.

In at least one embodiment, the design and preparation files may be used to derive a normalized coordinate format, which may be applied at each step of methods 300 and 1400. The normalized coordinate format may include 3D coordinate points. The 3D coordinate points may be relative to a Cartesian coordinate point (e.g., point (0,0,0)) capable of operating as a common reference point for discrete data sets. Discrete data sets, such as the solid model data and the parts of interest data described in detail above, may derive a common coordinate system from the common reference point of the normalized coordinate system. As a result, the systems 202, 1200, and 2500 may utilize a universal coordinate system across multiple data sets and data types (e.g., CAD files, OBJ-like files, CSV files, JavaScript Object Notation (JSON) files, OBJ files, stereolithography (STL) files, Standard for the Exchange of Product (STP) files, Initial Graphics Exchange Specification (IGS) files, PLY files, Extensible Markup Language (XML) files, HyperText Markup Language (HTML) files, Structured Query Language (SQL) database files), facilitating efficient universal communication of information such as target points, planes, surfaces, and polygons on which to perform measurements. In at least one embodiment, information may be communicated in a hierarchical manner such that a system may navigate first to a target component, then to a target surface of the target component, then to a target point on the target surface, where a measurement may be centralized by the target point. In at least one embodiment, coordinate information stored according to a normalized coordinate format may be stored as data object files having serialized values, flat values, structured values, and the like (e.g., JSON files, XML files, HTML files, SQL database files, TAML files, TOML files, CSV files).

Both the solid model and data files will be separable into common wear parts of the drill bit 100, such as the blades 104 (FIG. 1), the cutting elements 110 (FIG. 1), and the gauge pads 112 (FIG. 1). Furthermore, individual cutting elements such as PDC cutters could be separated into the two main components, PDC diamond table and tungsten carbide substrate. This separable data will be required to enable the computer system 204 to run the wear data quantification programming instructions (e.g., macros) described herein and obtain wear data quantification for individual (discrete) wear parts, as opposed to a volumetric material loss for the drill bit as a whole, or performing manual procedures to quantify wear.

The solid model file may be saved in the computer system 204 (FIG. 2) such that the common wear parts of the drill bit 100 are separately identified but embedded in a main assembly file. Accordingly, the main assembly file is comprised of the bit body 102 (FIG. 1) along with the wear parts and any other discrete parts or components that are cast, welded, or otherwise attached to the bit body 102.

Similarly, the data file may be saved in the computer system 204 (FIG. 2) with separate wear parts of the drill bit 100 being separately identifiable, as is common to data files. More specifically, the data file may include various part parameters related to the drill bit 100, such as bit size, bit description, scale CAD factor, the CAD part name for each cutting element 110 (FIG. 1), a list of cutting element 110 numbers (as assigned in the main assembly CAD file), the CAD part name for each blade 104 (FIG. 1), the corresponding blade 104 number for each cutting element 110, the nominal area/volume value for each cutting element 110, wear tolerances (if applicable/desired), nominal gauge diameter for the bit body 102 (FIG. 1), DOCC elements, and features of any DOCC elements.

In the event some of the cutting elements 110 comprise shaped (non-cylindrical) cutters, which exhibit a different nominal value than traditional cylindrical cutters, the data file may include (indicate) the appropriate nominal value for each cutting element 110. In some embodiments, for example, shaped and cylindrical cutting elements 110 may be used in an alternating layout along the blades 104 (FIG. 1) based on the radial position of the cutters on the profile. In such embodiments, the appropriate nominal area value may be applied to the varying cutter geometries to ensure accurate area/volume wear measurements, which would otherwise be erroneous if only one nominal value were applied to all cutting elements 110.

The well tool may then be properly situated in preparation for scanning, as at 304. The drill bit 100, for example, may be positioned on the stand 206 (FIG. 2) adjacent the scanner 202 (FIG. 2). In some embodiments, properly situating the drill bit 100 on the stand 206 may entail aligning one of the blades 104 (FIG. 1) with a predetermined angular orientation or coordinate (e.g., 270°). Such alignment may prove advantageous in enabling operators (e.g., scanner operators) to automate subsequent scanning processes with drill bits having the same part number. In other embodiments, a fixturing apparatus could be used to facilitate consistent alignment of the well tool when situating the well tool on a stand for scanning. In this scenario, the fixturing would also be modelled with the well tool to aid in alignment. In yet other embodiments, a datum feature could be designed into the well tool to allow for a datum-based alignment process.

Various tool data corresponding to the drill bit 100 may then be uploaded to the computer system 204 (FIG. 2) by the user to enable the computer system 204 to subsequently relate a scanned file of the drill bit 100 with the design and preparation CAD and data files. Example tool data that may be uploaded include, for instance, the part number, the serial number, and operation information for the drill bit 100. The operation information refers to where the drill bit 100 was used (commissioned), and such information may be subsequently correlated to the wear data. In some embodiments, the tool data corresponding to the drill bit 100 may be manually uploaded to the computer system 204. In other embodiments, however, the tool data may be obtained and uploaded electronically, such as by scanning a barcode corresponding to the specific drill bit 100, which will automatically upload the corresponding tool data from a database or data file, or both.

The well tool may then be scanned, as at 306. As indicated above, the scanner 202 (FIG. 2) may be operated to obtain multiple scanned images (3D or 2D) of the drill bit 100 from all angles and covering all exterior surfaces of the drill bit 100. These images may be subsequently transmitted to the computer system 204 (FIG. 2) for processing and generation of a scanned file corresponding to the drill bit 100, as at 308.

Once the scan of the well tool is complete, the computer system 204 may be programmed to run a first or “data import and preparation” programming instruction. In some embodiments, the 3D modeling and metrology software stored on the computer system 204 is automatically opened upon scan completion, and the 3D modeling and metrology software may be programmed to run the data import and preparation programming instruction. The data import and preparation programming instruction instructs the computer system 204 to import the 3D images obtained by the scanner 202 (FIG. 2) and generates the scanned file from the 3D images. As provided above, the scanned file consists of a 3D model comprising a complex polygon mesh structure corresponding to the scanned dimensions and configurations of the drill bit 100.

The data import and preparation programming instruction also instructs the computer system 204 to load the applicable design and preparation files corresponding to the drill bit 100. More specifically, the solid model files related to the drill bit 100 are loaded based on the tool data entered by the user prior to scanning the drill bit 100; e.g., the part number, the serial number, etc. of the drill bit 100. Moreover, the solid model files may be organized and renamed based on the dialogue tree of the data (e.g., CSV) files corresponding to the drill bit 100. This may be advantageous in organizing the cutting elements 110 (FIG. 1) by blade 104 (FIG. 1) and relative cutter position for subsequent feature generation, wear calculations, and reporting. In some applications, the dialogue tree includes the main assembly CAD model expanded with a view of the embedded parts of the well tool. The dialogue tree can include native naming and organization of other embedded parts that make up the main assembly. For example, the cutting elements 110 (FIG. 1) can be designated in the dialogue tree for wear calculations in an updated organization and naming sequence to facilitate preferred reporting. In at least one embodiment, the dialogue tree includes branch names, object names (including measurements, color maps, etc.), index numbers, and icons.

The method 300 may further include aligning the scanned file of the well tool with the solid model file corresponding to the well tool to obtain an overlay or “mated” output, as at 310. In some embodiments, properly aligning the scanned file with the solid model file may comprise three or more alignment steps or stages that may be performed to ensure proper alignment for the subsequent programming instructions that will be run to accurately record wear data. In the first alignment step, the data import and preparation programming instruction may prompt the user to undertake a manual point pair alignment between the scanned file and the corresponding solid model file, as at 312. Manual point pair alignment may be used to generally align the scanned file with the solid model file, and helps positively locate and identify wear parts of interest in the drill bit 100, such as each cutting element 110 (FIG. 1), each blade 104 (FIG. 1), and each gauge pad 112 (FIG. 1). This can be done by marking particular surfaces or parts on the solid model file with a unique identifier, and then making a corresponding mark on the same surfaces or parts of interest provided by the scanned file.

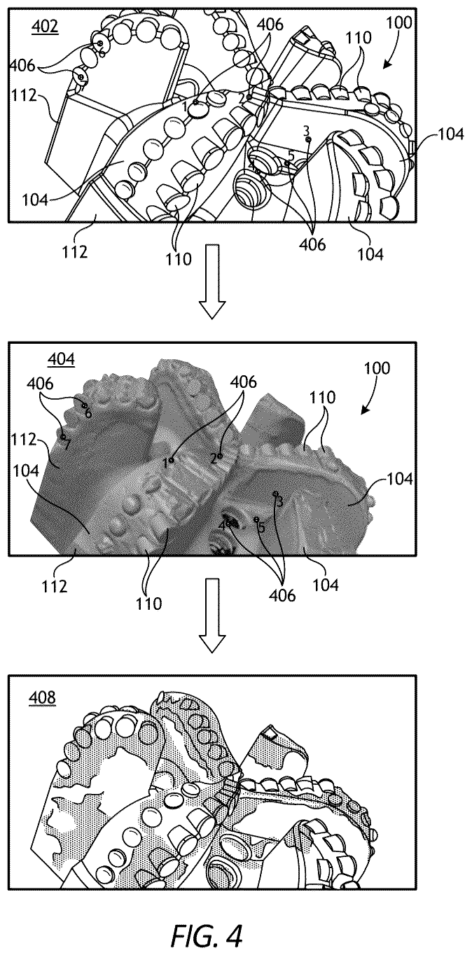

Referring briefly to FIG. 4, illustrated is an example solid model file output 402 and an example scanned file output 404 on which manual point pair alignment has been undertaken, according to one or more embodiments. As illustrated, several particular surfaces and parts of the drill bit 100 have been manually (e.g., electronically via a computer) marked by the user on the solid model file output 402 with unique identifiers 406. Corresponding marks in similar locations have also been manually placed on the scanned file output 404 with the same unique identifiers 406 to indicate the same surfaces and parts of interest, thus linking the solid model file to the scanned file. Consequently, the cutting elements 110 included in the solid model file will be aligned with the corresponding cutting elements 110 provided in the scanned file, the blades 104 included in the solid model file will be aligned with the corresponding blades 104 provided in the scanned file, and the gauge pads 112 included in the solid model file will be aligned with the corresponding gauge pads 112 provided in the scanned file.

The result of the manual point pair alignment is an overlay (mated) output 408 of the CAD and scanned files, which provides a rough alignment of the two file outputs 402, 404. In some embodiments, the manual point pair alignment may require 5 to 20 or more unique identifiers 406 to be placed on both the solid model file output 402 and the scanned file output 404 to achieve the rough alignment. In at least one embodiment, the manual point pair alignment step 312 may alternatively be automated by using datums and cutter position files.

Referring again to FIG. 3, in one or more embodiments, the manual point pair alignment of step 312 may be required only for new (unknown or not previously scanned) well tools with new (unknown) part numbers. For example, when a subsequent drill bit having the same part number as the drill bit 100 is scanned, the data import and preparation programming instruction may be configured to automate the point pair alignment for the subsequent drill bit since its features and design will be the same as the previously scanned and aligned drill bit 100. Automating the point pair alignment for additional well tools with same part numbers may be possible, however, only if the well tools are properly situated (oriented) and aligned for scanning, as discussed above in step 304.

Once the point pair alignment occurs, a second alignment step may ensue to globally align the scanned file with the solid model file, as at 314. More specifically, the data import and preparation programming instruction may then trigger a global alignment performed within the 3D modeling and metrology software that takes the rough point pair alignment and transforms it to a tighter alignment. In this process, a best-fit global alignment is created between all surfaces of the scanned mesh and solid model file outputs 402, 404 (FIG. 4), which provides a more accurate alignment between the scanned mesh and solid model files. In this process, all surfaces of the well tool may be utilized to achieve a best-fit alignment.

In some embodiments, a third alignment step may then be undertaken to perform a local alignment of individual wear parts of the well tool requiring wear calculations, as at 316. The third alignment step takes into consideration shrinkage in manufacturing processes of cast bits that may cause the scanned file to deviate from the solid model file based on manufacturing deviations or tolerances. More specifically, this step is designed to remove inconsistencies in positioning of the wear parts between the solid model and scanned files that result from shrinkage and/or deviations inherent in any manufacturing processes. This is accomplished by performing alignments on the individual wear components on an individual basis, thus eliminating the bit body and any positioning inconsistencies. Without this step, if a given wear part were out of position by even a small degree, the point clouds would not represent the wear part but rather the region surrounding the wear part.

In some embodiments, step 316 may alternatively be accomplished using a local best fit to critical feature alignment method. The local best fit to critical feature alignment may be undertaken to improve local cutter alignment if a substantial portion of the tungsten carbide substrate or cutting/diamond table are worn or missing. For instance, if the tungsten carbide substrate on the back portion of the cutter has suffered severe erosion, the alignment step could be skewed because so much of the feature is missing. An improved alignment could be performed by aligning only “critical features” of the cutter that did not sustain wear. In this example, this may entail using the cutting/diamond table only for alignment purposes. As will be appreciated, the inverse could be applied if the cutting/diamond tables are substantially worn or missing. The local best fit to critical feature alignment method may be done manually by an operator, or the process may be automated using the computer system 204.

In some embodiments, the data import and preparation programming instruction in the third alignment step 316 may be programmed to provide local alignment of each cutting element 110 (FIGS. 1 and 4) and cutter cylinder of the scanned file with the corresponding portions of the 3D file. This step reduces the alignment process to only cutter surfaces since without accurate local cutter-to-cutter alignment, the resulting wear data would be erroneous. As a result, each cutting element 110 is aligned on a one-by-one basis for optimal alignment, and regardless of deviations present between the scanned mesh and solid model files.

Once the alignment sequence(s) is/are complete, as at 310, the method 300 may then proceed to create features on wear parts of the scanned file requiring wear calculations, as at 318. More specifically, once alignment is complete and the overlay output 408 (FIG. 4) is generated, the computer system 204 may be programmed to run a second or “create dimensions” programming instruction, which may be programmed into the 3D modeling and metrology software. The create dimensions programming instruction may be configured to create and place digital features on specific wear parts of the overlay output 408 of the drill bit 100 that will undergo wear calculations.

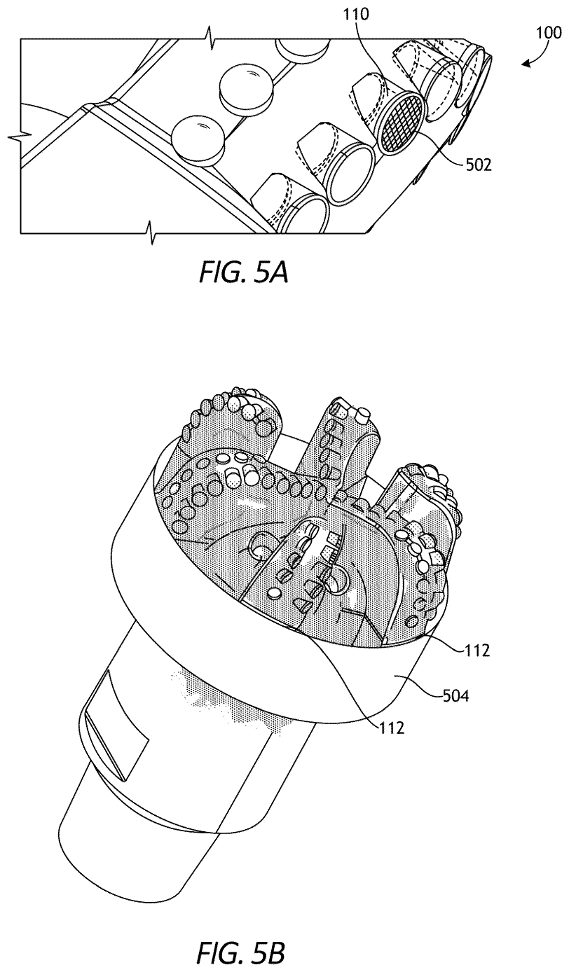

Referring to FIG. 5A, in some embodiments, a digital feature in the form of a digital plane 502 may be created and aligned with the cutter face of each cutting element 110 of the drill bit 100, and based on values obtained from the data file corresponding to the drill bit 100. As illustrated, the digital plane 502 may comprise a circle, an ellipse, or any other geometric shape sufficient to align with the corresponding cutter face of each cutting element 110.

Referring to FIG. 5B, in other embodiments, or in addition thereto, a digital feature in the form of a digital cylinder 504 may be created and aligned with the gauge pads 112 of the drill bit 100. More specifically, the digital cylinder 504 may be created based on the manufactured diameter of the drill bit 100, as obtained from the corresponding data file, or as extracted/measured from the CAD model. The digital cylinder 504 may help determine the gauge diameter measurement when undertaking wear calculations, thus helping determine the true (actual) gauge of the drill bit 100 after it exits the wellbore. This may help quantify the amount of material removed, and may also help specify if the gauge pads 112 are out of tolerance, if at all, and by what amount.

Referring again to FIG. 3, the method 300 may further include calculating the deviation between the solid model file and the scanned file at each wear part and thereby determining material removed from the wear parts of the well tool, as at 320. Once all the digital features have been created, the computer system 204 may be programmed to run a third or “volume/area calculation” programming instruction, which may be programmed into the 3D modeling and metrology software. The volume/area calculation programming instruction may be configured to retrieve nominal values that were set for the cutter dimensions (e.g., area and/or volume) of each cutting element (FIGS. 1, 4, and 5A) and the outer diameter of the bit body 102 (FIG. 1) at the gauge pads 112 (FIGS. 1, 4, and 5B). Such nominal values may be retrieved from the data file or CAD dimensions corresponding to the drill bit 100. The volume/area calculation programming instruction may then be programmed to compare the nominal values to the scanned file to quantify the area or volume removed from the wear parts, or wear scar distance at the wear parts. In some embodiments, the diamond area removed (DAR) from the cutting elements 110 and the amount of material removed at the gauge pads 112 may be determined.

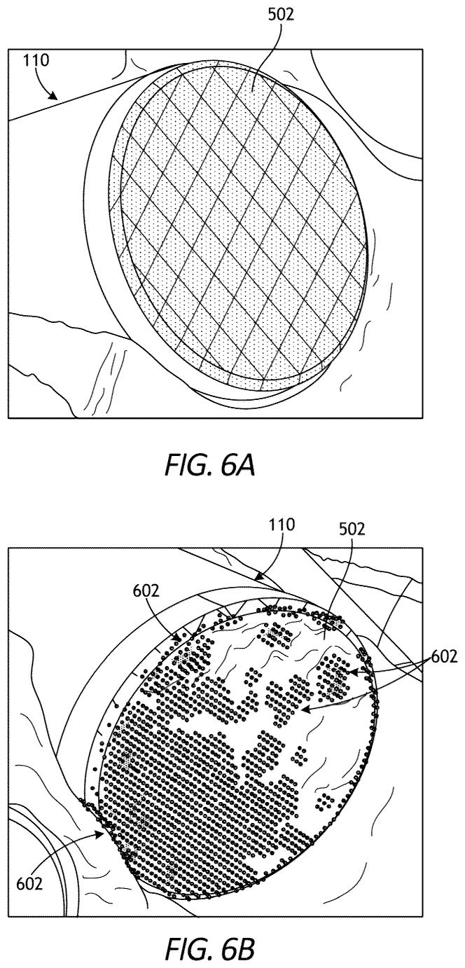

Referring to FIGS. 6A and 6B, depicted are enlarged images of an example cutting element 110 demonstrating surface area material loss, according to one or more embodiments. More specifically, FIG. 6A depicts the cutting element 110 with the digital plane 502 applied thereto and aligned with the cutting face, as generally described above. The volume/area calculation programming instruction may be programmed to use predetermined presets to measure the distance from the digital plane 502 to the actual scanned surfaces of the scanned file. The predetermined presets (e.g., alignment parameters) define at what depth to look for point clouds. This takes into account minor misalignments that can occur as well as spalling or thin layers of diamond loss. FIG. 6B depicts point cloud data points 602 where the digital plane 502 aligns with the scanned file at the cutter table. Locations on the cutter face where no point cloud data points 602 are observed represent areas where the cutter table has eroded or worn away.

The volume/area calculation programming instruction may be programmed to quantify the area of the point cloud data points 602 and assign a value to each cutting element 110. From that value, the volume/area calculation programming instruction may be programmed to calculate the DAR for each cutting element 110 and may place all measurements into comma separated variable (CSV) format as well as assign calculations in the corresponding dialogue tree. Associating the DAR values with the individual cutting elements 110 in the dialogue tree of the metrology software helps facilitate viewing and/or reporting visual annotations of the DAR values on the model within subsequently-generated reports and/or the software. As will be appreciated, similar calculations can be undertaken at the gauge pads 112 (FIGS. 1, 4, and 5B) using the digital cylinder 504 to determine how much material was removed from the outer diameter of the drill bit 100 during operation.

Referring again to FIG. 3, the method 300 may further include generating one or more reports detailing quantified wear data, as at 322. More particularly, the computer system 204 may be programmed to run a fourth or “auto-generate report” programming instruction, which may be programmed into the 3D modeling and metrology software. The auto-generate report programming instruction may be configured to generate a variety of types of reports. In some embodiments, the auto-generate report programming instruction may be programmed to produce a PDF report with a corresponding data file containing images and tabular quantified wear data for each of the cutting elements 110 (FIGS. 1, 4, and 6A-6B) listed in the data file for the drill bit 100. The PDF report may provide, among other features, color or “heat” maps of the drill bit 100, which detail where erosion occurred and its severity. In such embodiments, a legend may be provided based on pre-determined tolerances of wear severity. Moreover, calculated values for the cutting elements 110 may be placed in a table below each image for user reference.

The PDF report may further provide various images for each blade 104 (FIG. 1) and key areas of interest on the drill bit 100. More specifically, the auto-generate report programming instruction may be configured to obtain and produce still images of each blade 104. In some embodiments, the PDF report may provide gauge diameter calculations, which provide measurements on how much material was lost at or near the gauge pads 112 (FIG. 1) of the drill bit 100.

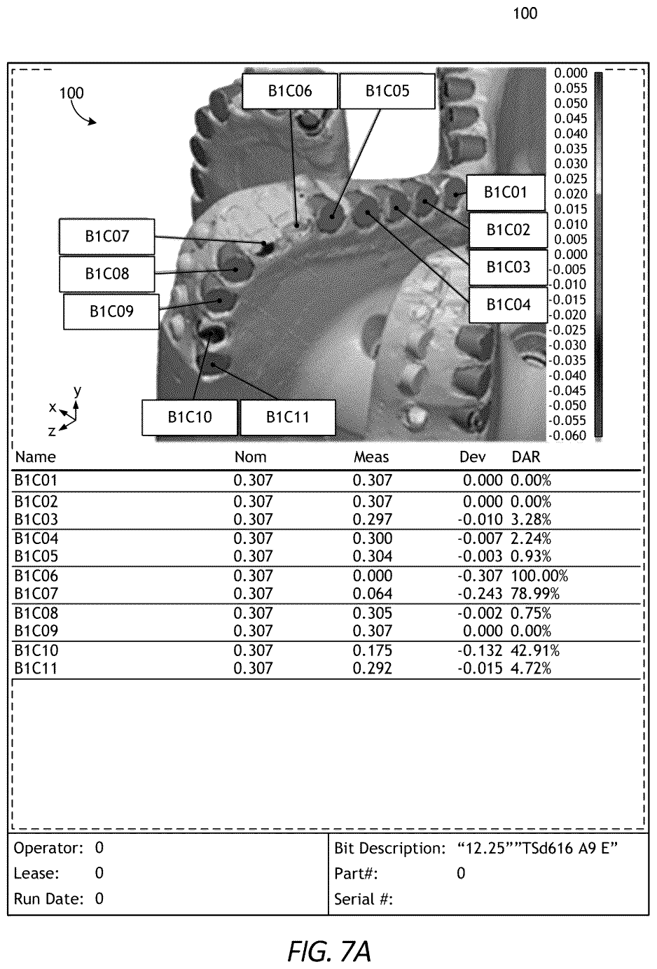

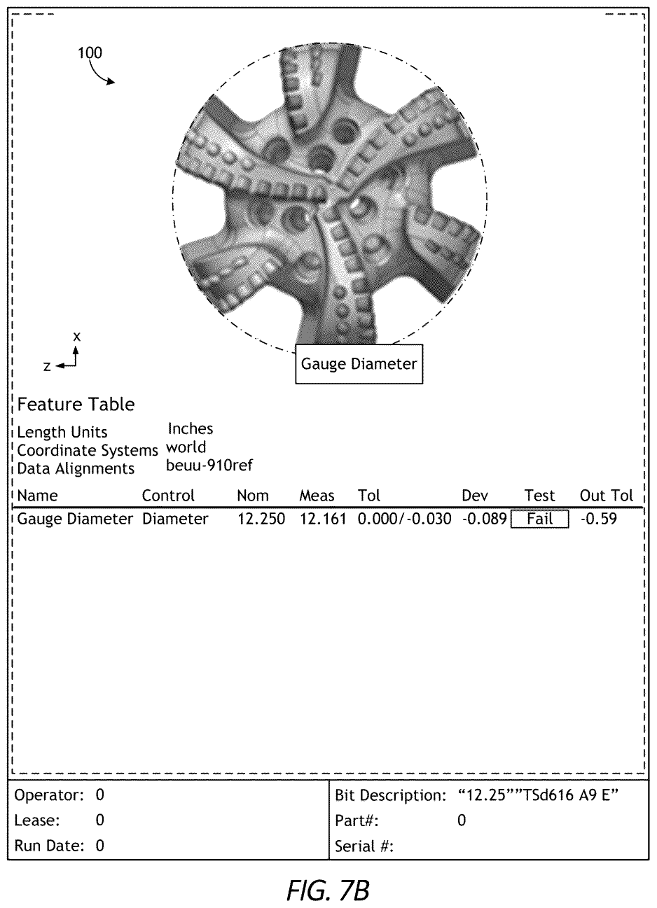

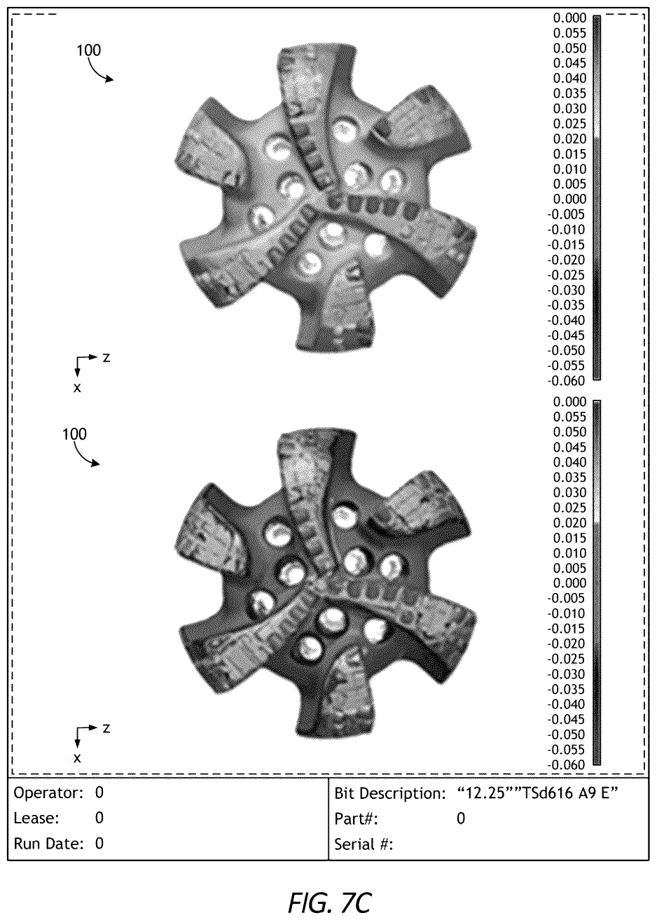

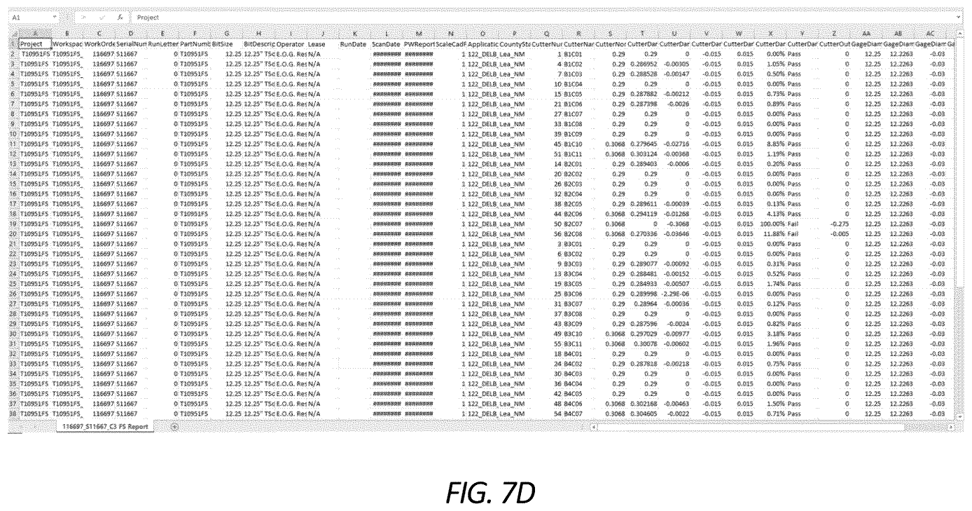

FIGS. 7A-7D depict example wear data reports that may be generated using the auto-generate report programming instruction, according to one or more embodiments. In FIG. 7A, unique annotations may be generated for each cutting element to provide details of wear data; i.e., how much material loss occurred for each individual cutting element. In some embodiments, as illustrated, the severity of material loss may be reported graphically with a color-coded graphical output, where different colors correspond to differing amounts of material loss. The report in FIG. 7A also includes tabular quantified wear data for each of the cutting elements 110. This reporting helps the operator and tool company to visually correlate the tabular wear data to the physical location across the profile of the well tool to better understand potential root causes of the wear.

In FIG. 7B, gauge diameter calculations for the drill bit 100 are provided, which provide determinations on how much material was lost at or near the gauge pads 112 (FIG. 1) of the drill bit 100. Accordingly, this report aids in visual correlation of the gauge diameter and how this measurement is being acquired.

FIG. 7C depicts a report that applies a color map overlay to images of the drill bit 100 as a visual representation of the wear and deviations being reported on the drill bit 100. As indicated above, the severity of material loss may be reported graphically and color-coded, where different colors correspond to differing amounts of material loss. This visual representation of material loss across the entire bit head can be helpful in evaluating hydraulic erosion trends to validate and/or optimize CFD modeling as well as visualizing wear patterns as related to radial location on the bit.

FIG. 7D depicts an example CSV wear report that may be generated following the presently described automated inspection process, according to one or more embodiments. The CSV wear report output (or similar tabular report) may contain large amounts of data captured during the automated inspection process including bit description, application details, nominal area values, measured area values, diamond area removed, gauge diameter, and tolerances, among many other variables/metrics. At least one advantage to having detailed inspection data in a plain text CSV file format is that the user can easily import the comprehensive dataset into many different applications and/or databases for storage and/or analysis.

Once wear data for the drill bit 100 is calculated and collected, it is contemplated herein to optimize subsequent drill bit design and/or manufacturing processes based on the wear data. More specifically, by knowing the drilling conditions the drill bit 100 undertook during operation and the resulting wear data, subsequent drill bits can be designed or manufactured to reinforce certain wear parts or regions of the bit to prolong its lifespan. Optimizing subsequent drill bit design and/or manufacturing, for instance, may entail a correlation analysis to identify volume or rock removed, cut area, weight on bit, torque on bit, distance traveled, hydraulic energy, depth of cut, formation unconfined compressive strength, mechanical specific energy, and other operation parameters. Once the wear for a specific cutting element within the drilling environment is determined, this can be used to optimize the design or cutter type for subsequent drill bits and thereby maximize performance when drilling in similar drilling environments and under similar drilling conditions.

In some embodiments, the methods described herein may include conducting an economic analysis of wear and/or wear rate for various material types to determine association between cost and performance.

In some embodiments, the methods described herein may include correlating electronic drilling recorder (EDR) data to quantified wear data to determine depth of cut and/or energy applied to the well tool. In such embodiments, the EDR data may be compared to the wear data to potentially identify optimal parameters in order to mitigate (reduce) the wear. In some embodiments, this correlation process may allow operators to determine wear rate per foot drilled. In at least one embodiment, correlating the wear rate per foot drilled may take into consideration any forces acting on the individual wear parts of the drill bit; e.g., weight on bit, torque on bit, hydraulic energy, RPM, etc. This analysis may be beneficial in helping to modify the design of the drill bit for improved performance and longevity, and/or optimize the drilling parameters to maximize bit life.

In some embodiments, a wear index may be created and applied for specific drilling applications and/or formations drilled using the drill bit 100, and thereby helping to predict wear probability. The wear index could be created once a large enough data set is obtained and correlated to specific formation drilling applications. The wear index may be obtained or determined, at least in part, by using various statistical analysis and modeling methods, such as linear regression. In such embodiments, coefficients and weights for various known downhole forces may be applied in the analysis and may be useful in predictive modeling that can estimate wear given specific changes to the design and/or materials of the drill bit 100. In at least one embodiment, the wear index could be on a scale of 1-10, but could alternatively be on a different type of scale, without departing from the scope of the disclosure. In such embodiments, increments of the wear index may be equated to certain types of drill bits used in particular drilling applications to maximize performance. Accordingly, the increments of the wear index may correspond to specific drilling applications and/or formations and may include correlation of rock strength analysis and/or unconfined compressive strength (UCS) with wear.

Sectioned Cutters

During the repair process of drill bits (e.g., PDC bits), worn cutters are commonly detached from the cutter pocket and turned (rotated) to orient an unworn or new cutting edge toward the point of contact with the underlying rock. In such processes, worn portion(s) of the cutter are turned (rotated) down into the cutter pocket in order to avoid being directly exposed to contact with the rock being drilled. Some cutters may be turned (rotated) three or four times before scrapping the cutter, and each time the cutter is turned, an undamaged (sharp) cutter edge is exposed and aligned with the point of contact for a subsequent run downhole. This process can save money by utilizing each cutter to its maximum potential.

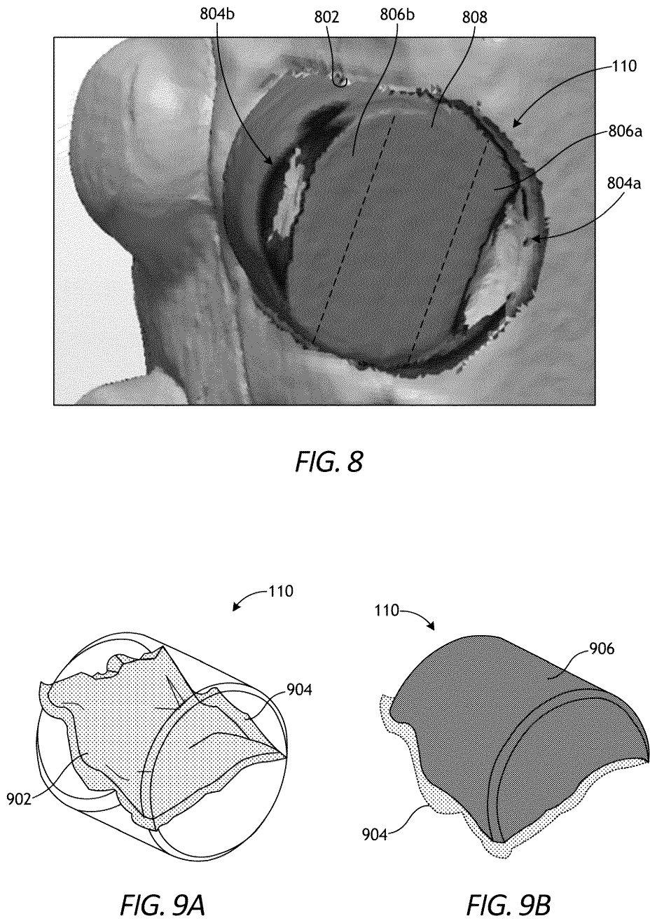

Referring to FIG. 8, illustrated is an enlarged scanned view of a worn cutter 110 seated within a corresponding cutter pocket 802. As illustrated, the cutter 110 has a first worn edge 804a and a second worn edge 804b, thus evidencing that the cutter 110 has been used in at least two runs and detached and rotated within the cutter pocket 802, as generally described above. As a result, the first worn edge 804a is oriented away from the point of contact with the rock and the second worn edge 804b is oriented toward the point of contact.

It may be desired to determine the wear and/or diamond area removed (DAR) from the cutting element 110 during the last operation (e.g., the last run or trip downhole). To do this, an operator may follow the steps of the method 300 of FIG. 3, but the resulting wear measurements obtained using the method 300 would be skewed for the last run since it would determine wear and/or DAR for both worn edges 804a,b, whereas the wear and/or DAR for the second worn edge 804b is only desired.

According to embodiments of the disclosure, the CAD file of the cutting element 110 may be digitally divided into two or more sections that include corresponding two or more cutting edge portions of the cutting element 110 to be analyzed for wear. In the illustrated embodiment, the cutting element 110 is digitally divided into a first section 806a and a second section 806b, where the first section 806a encompasses the first worn edge 804a and the second section 806b encompasses the second worn edge 804b. The first section 806a may be characterized as an “unexposed” section since the first worn edge 804a is oriented away from contact with the rock, whereas the second section 806b may be characterized as an “exposed section” since the second worn edge 804a is oriented toward contact with the rock. In this embodiment, the first and second sections 806a,b comprise sections corresponding to approximately 30% of the surface area of the cutter face 808. In other embodiments, however, the sections 806a, b may comprise other surface area percentages of the cutter face 808, such as up to 50% each. In yet other embodiments, the cutting element 110 may be digitally divided into more than two sections, such as three or four sections. In embodiments with four sections, the sections may each encompass 25% of the surface area of the cutter face 808, for example.

In this embodiment, step 320 of the method 300 of FIG. 3 may be modified and otherwise further include calculating the deviation between the solid model file and the scanned file at an exposed section of the cutting element 110, such as the second section 806b, while disregarding (ignoring) the unexposed section(s), such as the first section 806a. As a result, the determination of material removed from the cutting element 110 will be isolated to only the second section 806b, which includes the second worn edge 804b, while any wear present in the first section 806a, including the first worn edge 804a, will be omitted from the resulting wear calculation. As will be appreciated, this will generate wear calculations for the cutting element 110 corresponding to the most recent run, while omitting wear (losses) on the cutting element 110 resulting from any prior runs, which would skew the overall data.

### Correlating Wear to Downhole Drilling Dynamics

It is contemplated herein to install various sensors in downhole well tools to obtain data related to the well tool during downhole operation, and correlate that data to subsequent observed wear. More particularly, one or more sensors may be installed in the drill bit 100 and designed to monitor (detect) various downhole drilling dynamics including, but not limited to, vibration, acceleration, shock, orientation, temperature, weight on bit, pressure, or any combination thereof. This data may be tracked to better understand the specific dynamics experienced by the drill bit 100 during operation.

However, such data may also be correlated to the wear experienced on the drill bit 100 during operation to better understand the effect of drilling dysfunctions on cutter wear. This analysis may help an operator optimize drilling parameters, optimize parameter road mapping to mitigate tool dysfunction and wear, aid in bit and/or cutter design, and aid in material selection and optimization to mitigate tool dysfunction and/or wear.

### Automating the IADC Dull Grading System

As discussed herein, the International Association of Drill Contractors (IADC) developed and uses a dull bit grading system that provides a standardized protocol for evaluating drill bits and classifying drill bit wear/damage. In the IADC dull grading process, an evaluator visually inspects the dull bit and manually quantifies the observed wear using a standardized eight-field code; i.e., 0 to 8 scale, where 0=no wear, and 8 =effective cutting structure completely worn away. The current IADC dull grading system divides the bit into the inner ⅔ diameter of the bit body and the outer ⅓ of the bit body and assigns an average of the wear sustained on the cutters located in the inner ⅔ and the outer ⅓ to the 0 to 8 scale.

According to embodiments of the present disclosure, the basic evaluation principles provided by the IADC dull grading process may be automated using the methods described herein. In the presently disclosed embodiments, the computer system 204 may be programmed divide the bit body 102 (FIG. 1) of the drill bit 100 (FIG. 1) into two or more radial sections extending radially outward from the centerline 108 (FIG. 1) of the bit body 102. In some embodiments, two radial sections may be identified similar to the current IADC methodology, such as the inner ⅔ diameter of the bit body 102 and the outer ⅓ of the bit body 102. In other embodiments, however, other fractions of gauge diameter may be identified extending from the centerline 108. In yet other embodiments, more than two radial sections extending from the centerline 108 may be identified, without departing from the scope of the disclosure.

The average wear of the cutting elements 110 located within each identified radial section may then be determined in accordance with the wear calculation methods described herein, thus providing a percent diamond area removed or “% DAR”. The % DAR for each identified radial section may then be correlated with an industry standard dull grading system, such as the IADC system or another system. In such embodiments, the % DAR for each identified radial section may be applied to the IADC 0 to 8 scale and assigned a number between 0 and 8, depending on the resulting (calculated) % DAR. In other embodiments, however, the % DAR may be applied to any other grading scale system, without departing from the scope of the disclosure.

### Failure Mode Classification

While understanding the amount of wear sustained is critical in well tool (e.g., drill bit) optimization, understanding the way the wear was ultimately sustained during operation may also be important. By evaluating the characteristics of the wear, such as geometry, magnitude, direction, etc., it may be possible to classify the damage into specific failure modes and thereby facilitate a root cause analysis of the damage. Wear parts can fail due to a variety of root causes, for example, such as abrasion, thermal degradation, mechanical overloading, erosion, corrosion, manufacturing defects, oxidation, or any combination thereof.

FIG. 9A is an isometric view of an example cutting element 110 that graphically depicts sustained failure damage. More specifically, FIG. 9A depicts a failure surface 902 indicating where a large portion of the cutting element 110 was extracted during operation by reason of failure. According to embodiments of the present disclosure, one or more digital features 904 may be generated to overlay the failure surface 902 and thereby generally follow the surface (contour) of the damage. Similar to the digital features described above with reference to FIGS. 5A-5B, the digital feature(s) 904 applied to the failure surface 902 may constitute computer-generated surfaces overlaid onto the scanned data of the well tool. Depending on the geometry of the resulting digital feature(s) 904, an appropriate failure mode may then be assigned to the worn part. Example failure modes include, but are not limited to, smooth wear, thermal-mechanical wear, cracking, chipping, spalling, tangential fracture/break, delamination, etc.

The computer system 204 may also be programmed and otherwise trained to use machine learning and neural networks to aid in automated failure analysis and classification for individual wear parts. Failure mode classification could be achieved using various forms of artificial intelligence approaches. In example applications using machine or deep learning, example images of common (or less-common) failure modes may be used to train an artificial intelligence model on how to classify the failure modes accurately. Well tool wear classification systems and methods using machine learning are described in further embodiments below with respect to FIGS. 12-16.

In other applications, or in addition thereto, such as in rule-based artificial intelligence systems, the characteristics of the failure modes may be defined within coding in order for the computer system 204 to properly assign a failure classification.

In some embodiments, the resulting digital feature(s) 904 applied to the failure surface may then be compared to the CAD model of the wear part in order to model the missing portion of the wear part. FIG. 9B, for example, shows a graphical representation 906 of the missing part (material) from the cutting element 110 of FIG. 9A. The graphical representation 906 may prove advantageous in helping to determine the geometry and amount (volume) of material lost from the cutting element 110.

### Computational Fluid Dynamics

Upon calculating deviation between the solid model file and the scanned file at the digital features for the wear parts, and determining material removed from the wear parts of the well tool, it is also contemplated herein to compare (correlate) the determined wear data to computational fluid dynamics (CFD) modeling. Correlating wear to CFD results, in this instance flow lines, enables an operator (user) to confirm if the damage being sustained is related in some way to drilling fluid circulation, which may result in erosion and/or corrosion. In some embodiments, the CFD modeling may be generated from an add-in within CAD modeling/design software packages (e.g., SolidWorks).

CFD simulations can have a multitude of variables and/or parameters that an operator (user) can adjust to best fit the real world scenario or application. It is often difficult to determine the accuracy of the simulations, thereby leaving much room for ambiguity in selecting the most appropriate parameters to use during simulations. Having highly precise wear quantification, however, provides a much needed feedback system for the CFD analysts to evaluate (or validate) the accuracy of their simulations and adjust the parameters of the models as needed to better match the actual or observed effects of fluids on the well tool. Accordingly, comparing the wear data to CFD modeling may prove advantageous in helping to validate CFD modeling.

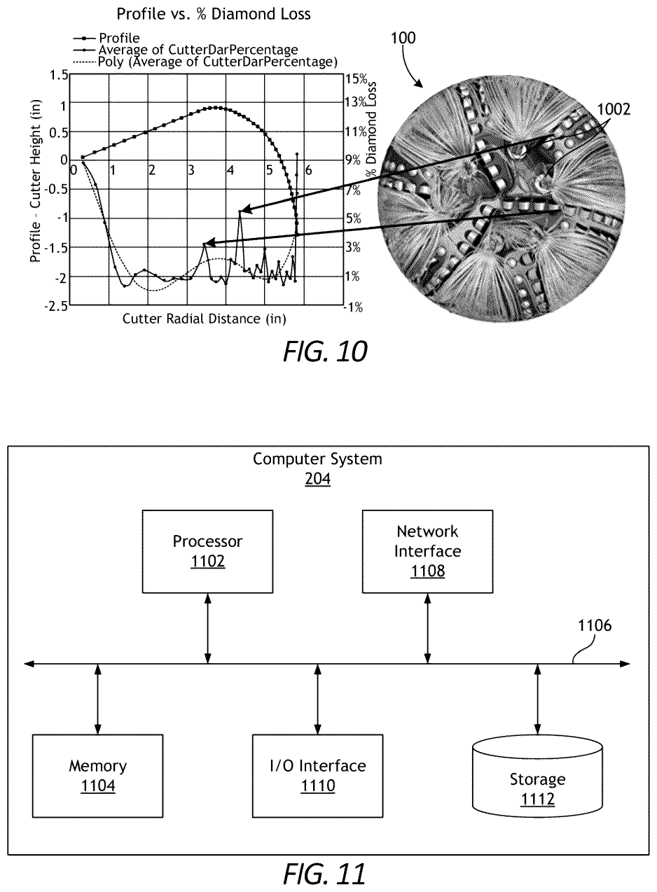

FIG. 10 depicts an example of observed CFD flow lines across a well tool (e.g., the drill bit 100) being correlated to cutting element wear, according to one or more embodiments. In the illustrated example, flow lines are observed traveling (flowing) across erosion-prone (relative to the diamond table) cutting element substrates on the CFD modeling, and a corresponding spike in % DAR is recorded in the adjoining graph. If the erosion-prone substrate sustains erosion, the diamond table of the cutting element may be left unsupported and is more likely to fail. With this understanding (data), an operator (user, designer, manufacture, etc.) may be able to adjust one or more parameters of the drill bit 100 to help prevent erosion. In some embodiments, for instance, the orientation of nozzles 1002 in the drill bit 100 may be adjusted to reduce the hydraulic flow traveling across the cutting elements, which may reduce the risk of fluid-related damage on the cutting elements. FIG. 10 provides an example of this relationship and phenomenon. Accordingly, in some embodiments, wear patterns identified on the drill bit 100 may be correlated to CFD modeling to optimize hydraulic layouts of the drill bit 100 and thereby minimize fluid erosion.

The methods and systems of the present disclosure may utilize computers and/or their components (e.g., processors) to execute the wear pattern analysis as described herein. For example, a system can include a computer system that comprises: one or more processors; and one or more tangible, machine-readable storage media that store machine-readable instructions for executions by the processors, the machine-readable instructions corresponding to one or more of the methods described herein. That is, the methods described herein can be performed on computing devices (or processor-based devices) that include one or more processors; one or more memory devices coupled to the processor(s); and instructions provided to the memory devices, wherein the instructions are executable by the processor(s) to perform the methods (or steps of the methods) described herein. The instructions can be a portion of code on one or more non-transitory computer readable media. Any suitable processor-based device(s) may be utilized or implementing all or a portion of embodiments of the present techniques, including, without limitation to, personal computers, networks of personal computers, laptop computers, computer workstations, mobile devices, multi-processor servers or workstations with (or without) shared memory, high performance computers, virtual machines, virtual devices, compute clusters, serverless compute architecture, containerized compute architecture, and the like. Moreover, embodiments may be implemented on application specific integrated circuits (ASICs) or very large scale integrated (VLSI) circuits.

In at least one embodiment, serverless computer architecture, containerized compute architecture, and the like may include “Kubernetes” architecture. Kubernetes is an open-source container orchestration platform that may manage containerized applications across a cluster of nodes. Within its architecture, several data types are integral to its operation and management. These data types include “Pods,” which are the smallest and simplest Kubernetes objects that represent a single instance of a running process in a cluster. “Nodes,” another critical data type, are the worker machines in Kubernetes, which can be either virtual or physical. Deployments are used to manage a set of identical Pods, ensuring that the desired number of Pods are running at any given time. Services, which define a logical set of Pods and a policy by which to access them, are essential for enabling network access to the Pods. “ConfigMaps” and “Secrets” are used to manage configuration data and sensitive information, respectively. “PersistentVolumes” and “PersistentVolumeClaims” handle storage resources, allowing Pods to request and use storage dynamically. Namespaces provide a mechanism to partition resources within a single Kubernetes cluster, facilitating multi-tenancy and resource management. In Kubernetes architectures, various types of databases can be deployed to manage and store data efficiently.

Accordingly, FIG. 11 is a schematic diagram of the computer system 204 of FIG. 1 and/or the computer system 2504 of FIG. 25. As shown, the computer system 204 and/or the computer system 2504 of FIG. 25 includes one or more processors 1102, which can control the operation of the computer system 204 and/or the computer system 2504 of FIG. 25. “Processors” are also referred to herein as “controllers.” The processor(s) 1102 can include any type of microprocessor or central processing unit (CPU), including programmable general-purpose or special-purpose microprocessors, any one of a variety of proprietary or commercially available single or multi-processor systems, and/or any processor suitable to perform the methods described herein. The processors may operate in sequence with one another and/or in parallel with one another. The computer system 204 and/or the computer system 2504 of FIG. 25 can also include one or more memories 1104, which can provide temporary storage for code to be executed by the processor(s) 1102 or for data acquired from one or more users, storage devices, and/or databases. The memory 1104 can include read-only memory (ROM), flash memory, one or more varieties of random access memory (RAM) (e.g., static RAM (SRAM), dynamic RAM (DRAM), or synchronous DRAM (SDRAM)), a compact disc random optical memory (CD-ROM), any other optical medium, a programmable ROM (PROM), and erasable PROM (EPROM), a FLASH-EPROM, a solid state medium like a holographic memory, a memory card, or any other memory chip or cartridge, any other physical medium from which a computer can read, and/or a combination of such memory technologies. The processor(s) 1102 and memories 1104 may be configured to perform any portion or the entirety of the method 300 and/or the method 2400.

The various elements of the computer system 204 and/or the computer system 2504 of FIG. 25 can be coupled to a bus system 1106. The illustrated bus system 1106 is an abstraction that represents any one or more separate physical busses, virtual busses, cloud-based busses, communication lines/interfaces, and/or multi-drop or point-to-point connections, connected by appropriate physical or virtual bridges, adapters, and/or controllers. The computer system 204 and/or the computer system 2504 of FIG. 25 can also include one or more network interface(s) 1108, one or more input/output (IO) interface(s) 1110, and the one or more storage device(s) 1112.

The network interface(s) 1108 can enable the computer system 204 and/or the computer system 2504 of FIG. 25 to communicate with remote devices, e.g., other computer systems, over a wired or wireless network, and can be, for non-limiting example, remote desktop connection interfaces, cloud-based interfaces, Ethernet adapters, and/or other wireless or local area network (LAN) adapters. The IO interface(s) 1110 can include one or more interface components to connect the computer system 204 and/or the computer system 2504 of FIG. 25 with other electronic equipment. For non-limiting example, the IO interface(s) 1110 can include high-speed data ports, such as universal serial bus (USB) ports, 1394 ports, Wi-Fi, Bluetooth, virtual ports, internal cloud-based ports, etc. Additionally, the computer system 204 and/or the computer system 2504 of FIG. 25 can be accessible to a human user, and thus the IO interface(s) 1110 can include displays, speakers, keyboards, pointing devices, augmented reality devices, and/or various other video, audio, or alphanumeric interfaces.

The storage device(s) 1112 can include any conventional medium for storing data in a non-volatile and/or non-transient manner. In at least one embodiment, the storage device(s) 1112 may be the same as the storage device 138 of FIG. 1. The storage device(s) 1112 can hold data and/or instructions in a persistent state, i.e., the value(s) are retained despite interruption of power to the computer system 204 and/or the computer system 2504 of FIG. 25. In at least one aspect, the database 136 of FIG. 1 may be located on the storage device(s) 1112. The storage device(s) 1112 can be block-level storage devices, object level storage devices, file-level storage devices, host-based storage devices, network-based storage devices, array based storage devices, or any combination herein that may be implemented on a physical or virtual machine. The storage device(s) 1112 can include one or more hard disk drives, flash drives, USB drives, optical drives, solid state drives, various media cards, magnetic tape drives, diskettes, compact discs, and/or any combination thereof and can be directly connected to the computer system(s) 204 and/or the computer system 2504 of FIG. 25 or remotely connected thereto, such as over a network. In an exemplary embodiment, the storage device(s) 1112 can include a tangible or non-transitory computer readable medium configured to store data, e.g., a hard disk drive, a solid state drive, a flash drive, a USB drive, an optical drive, a media card, a diskette, a compact disc, etc.

The elements illustrated in FIG. 11 can be some or all of the elements of a single physical machine. In other embodiments, however, and as mentioned above, the computer system 204 and/or the computer system 2504 of FIG. 25 may alternatively include two or more computers, virtual computing machines, cloud-based computing machines, or physical computing machines networked together or otherwise capable of communicating one with the other to achieve a common goal. In addition, not all of the illustrated elements need to be located on or in the same physical machine. In other words, the illustrated elements may be located on one or more physical machines as part of a physical machine network, a virtual machine, a cloud based machine, and the like. Exemplary computer systems (e.g., devices) include conventional desktop computers, workstations, minicomputers, laptop computers, tablet computers, personal digital assistants (PDAs), personal computers, networks of personal computers, mobile devices, multi-processor servers or workstations with (or without) shared memory, high performance computers, virtual machines, virtual devices, and the like.

The computer system 204 and/or the computer system 2504 of FIG. 25 can include a web browser for retrieving web pages or other markup language streams, presenting those pages and/or streams (visually, aurally, or otherwise), executing scripts, controls and other code on those pages/streams, accepting user input with respect to those pages/streams (e.g., for purposes of completing input fields), issuing HyperText Transfer Protocol (HTTP) requests with respect to those pages/streams or otherwise (e.g., for submitting to a server information from the completed input fields), and so forth. The web pages or other markup language can be in HyperText Markup Language (HTML) or other conventional forms, including embedded Extensible Markup Language (XML), scripts, controls, and so forth. The computer system 204 and/or the computer system 2504 of FIG. 25 can also include a web server for generating and/or delivering the web pages to client computer systems.

In an exemplary embodiment, the computer system 204 and/or the computer system 2504 of FIG. 25 can be provided as a single unit, e.g., as a single server, as a single tower, contained within a single housing, etc. The single unit can be modular such that various aspects thereof can be swapped in and out as needed for, e.g., upgrade, replacement, maintenance, etc., without interrupting functionality of any other aspects of the system. The single unit can thus also be scalable with the ability to be added to as additional modules and/or additional functionality of existing modules are desired and/or improved upon.

The computer system 204 and/or the computer system 2504 of FIG. 25 can also include any of a variety of other software and/or hardware components, including by way of non-limiting example, operating systems and database management systems. Although an exemplary computer system is depicted and described herein, it will be appreciated that this is for the sake of generality and convenience. In other embodiments, the computer system may differ in architecture and operation from that shown and described here.

### Well Tool Wear Classification Using Machine Learning

FIG. 12 is a diagram of a well tool wear classification system 1200 with machine learning, according to one or more embodiments. System 1200 includes a wear classifier tool 1210 coupled to a database 1220 and a machine learning (ML) engine 1230. ML engine 1230 is further coupled to a trained ML model 1232 and training dataset 1235. Wear classifier tool 1210 can also be coupled to trained ML model 1232 and training dataset 1235. Database 1220 can be used to store scanned images, sensor data, well tool data, historical data, live sensor data and other types of data that can used for training or inference in the operation ML engine 1230. Scanned images stored in database 1220 may include digital 2D image data, electronic drilling recorder (EDR) data and 2D images of various failure modes. Database 1220 is an electronic collection of data and can be stored in computer-readable memory locally or remotely from wear classifier tool 1210.

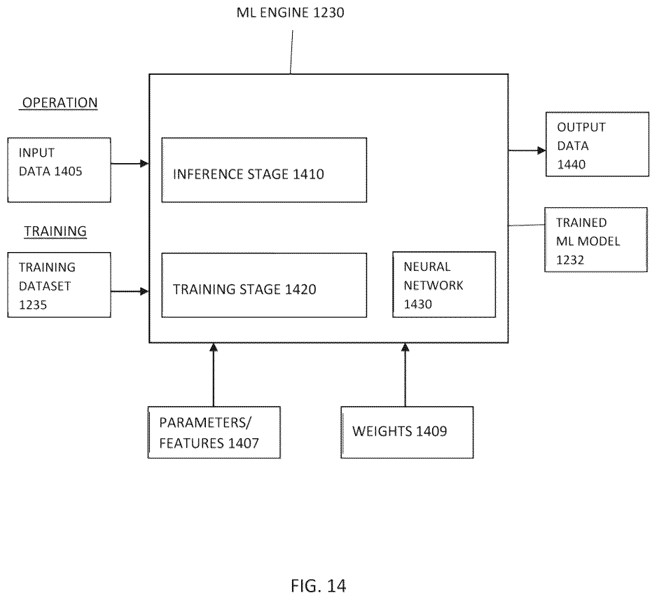

System 1200 operates to classify wear data for a well tool using machine learning. Wear classifier tool 1210 controls the wear classification of wear data for the well tool. Wear classifier tool 1210 controls the loading of training data into training dataset 1235. Wear classifier tool 1210 controls the operation of ML engine 1230 in training and inference stages, and can access trained ML model 1232. Wear classifier tool 1210 retrieves from and stores data in database 1220. Wear classifier tool 1210 further receives output from ML engine 1230. ML engine 1230 applies machine learning using trained ML model 1232 and training dataset 1235. The operation of system 1200 and its components are described further below with respect to process 1300 and examples in FIGS. 14-16. In embodiments, system 1200 can be coupled with scanning system 200 of FIG. 2 or scanning system 1700 of FIG. 17.

FIG. 13 is a process flow diagram of an example method for classifying a well tool 1300, according to one or more embodiments. In step 1310, a neural network is trained with a plurality of failure mode images to obtain a trained neural network (also called a model). For example, wear classifier tool 1210 (FIG. 12) can upload training data comprised of failure mode images and labels associated with classification types of the failure mode images to form training dataset 1235.

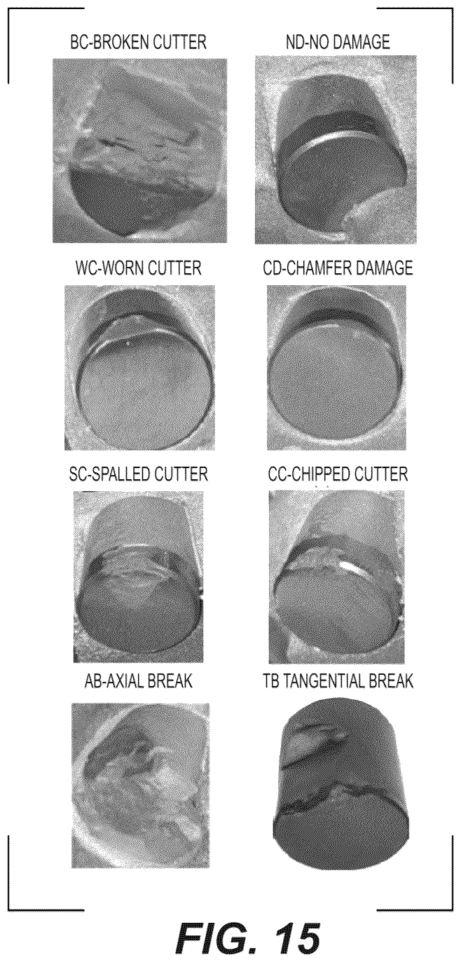

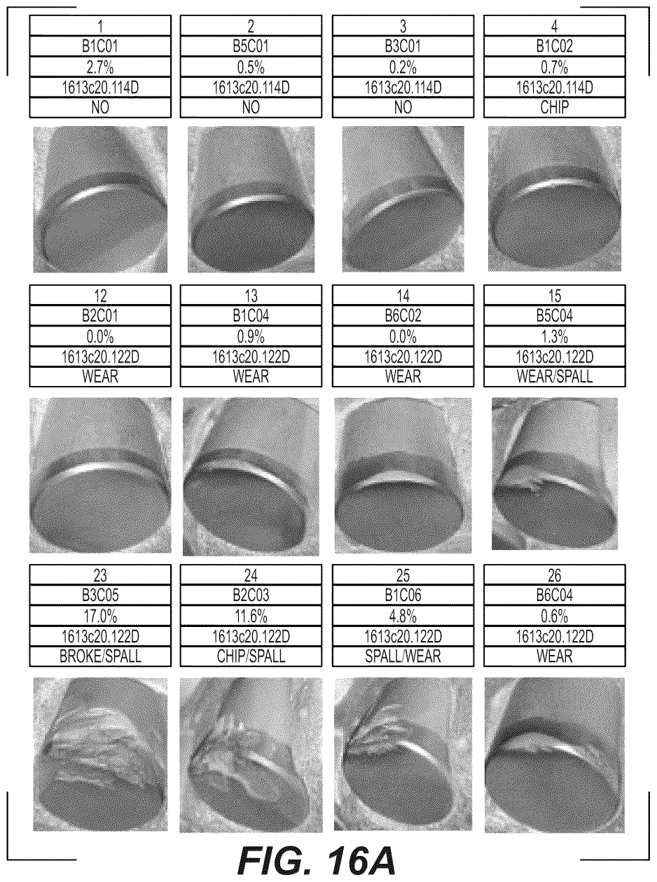

Referring briefly to FIG. 15, an example set of failure mode images for cutter failure modes for a cutting element that can be used as training data is shown. These types of failure modes (shown from left-to-right and then down) are BC-Broken Cutter, ND—No Damage, WC—Worn Cutter, CD—Chamfer Damage, SC—Spalled Cutter, CC—Chipped Cutter, AB—Axial Break, and TB—Tangential Break.

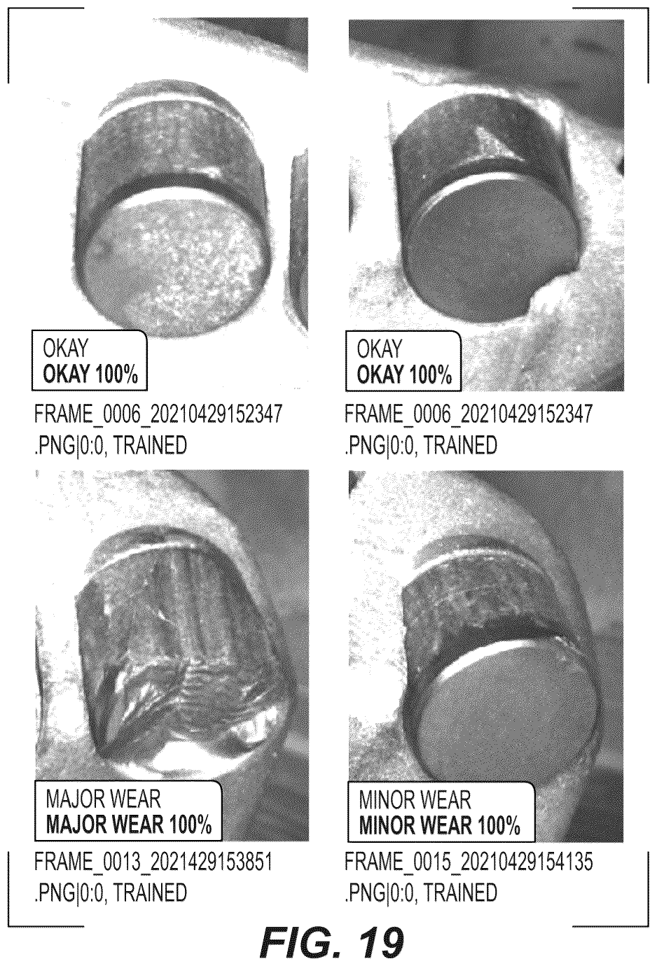

In one embodiment, image data showing different states of wear in different failure modes is used in training dataset 1235. FIG. 19 shows four example images of cutting elements for use in a training dataset 1235. The cutting elements are disposed in a substrate. For illustration here, images are overlaid with associated wear for particular cutting elements. Image (top left) shows a first cutting element determined with about 100% confidence to be in a condition (“OK”) with no or little wear. Image (top right) shows a second cutting element determined with about 100% confidence to be in a condition (“OK”) with no or little wear. Image (lower left) shows a third cutting element determined with about 100% confidence to be in a condition with major wear. Image (lower right) shows a fourth cutting element determined with about 100% confidence to be in a condition with minor wear.

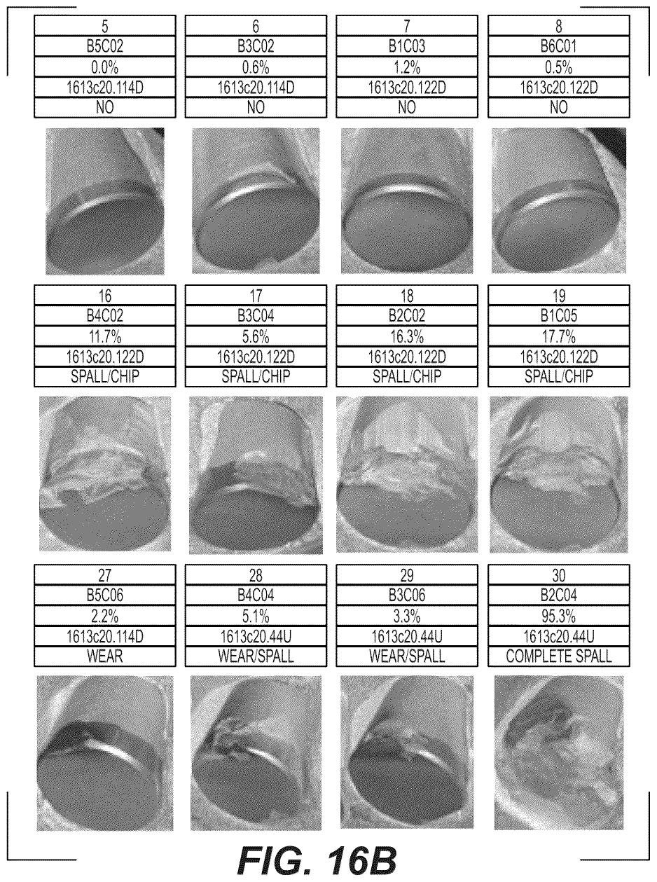

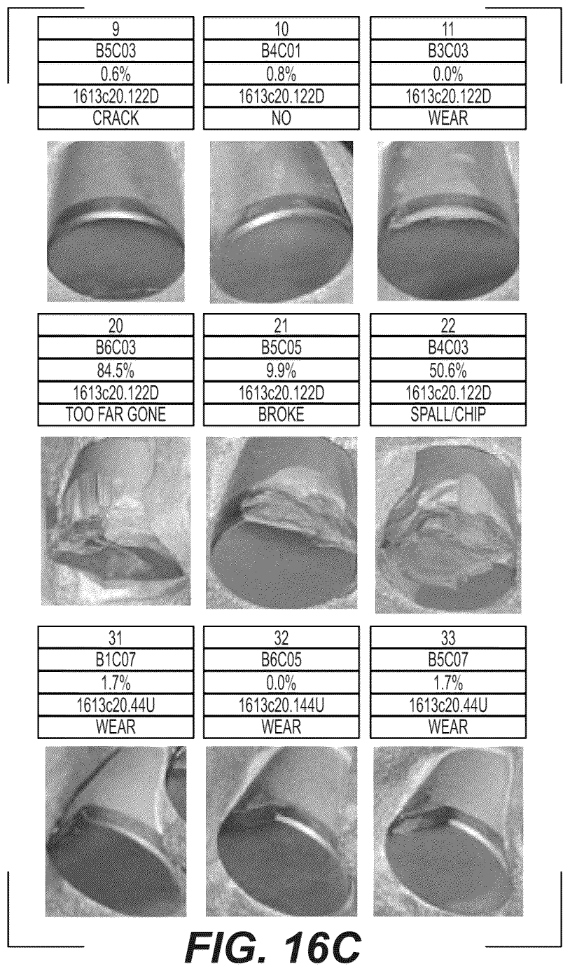

In addition to image data, other types of data and data sources may also be used as training data. This can include historical data and live sensor data. For example, and with reference to FIGS. 16A-16C, examples of automated radial position reporting for different cutting elements including classified failure mode and wear quantification data are shown. FIGS. 16A-16C illustrate visual reporting output of the individual cutter images, cutter position, cutter type, wear (DAR from 3D scanning) and failure mode (from 2D ML output). Radial reporting data fields along with values and thresholds for classification of wear by cutting elements can be used. Patterns of wear among cutting elements and their relative position on a drill bit can also be used as training data for multiple failure mode classification and/or for root cause classification of the wear trends. For instance, increased wear severity along with load related failure mechanisms in the inner or middle (cone or nose) portions of the bit profile would be indicative of axial overloading such as excessive weight on bit and/or bit bounce. Whereas increased wear severity along with load related failure mechanisms towards the outer diameter (OD) of the bit (shoulder and gauge) would be indicative of lateral and/or torsional overload events such as experienced with bit whirl and/or stick-slip.

Referring again to FIG. 13, in step 1320 a used well tool such as drill bit 100 is scanned. One or more cameras or other sensors that capture wear input data can be used. In embodiments, drill bit 100 may be scanned by scanning system 200 of FIG. 2 or scanning system 1700 of FIG. 17. In embodiments, scanner 202 may be used to capture 2D or 3D images of drill bit 100 as described above.

In further examples, camera 1702 and/or a 3D scanner 1704 may be used to capture 2D or 3D images of drill bit 100 respectively. For example, as shown in FIG. 17, drill bit 100 may be loaded onto a stand 1706. A first robotic arm 1704 controlled by computer system 204 can be operated to move camera 1702 relative to the drill bit 100 to scan drill bit 100 and capture a set of scanned images of drill bit 100 and its cutter elements. Also, once 2D scanning is complete the drill bit can also be moved to stand 1716 to perform 3D scanning. A second robotic arm 1714 controlled by computer system 204 can be operated to move 3D scanner 1712 relative to the drill bit 100 to scan drill bit 100 and capture a set of scanned images and distance data (3D images) of drill bit 100 and its cutter elements.

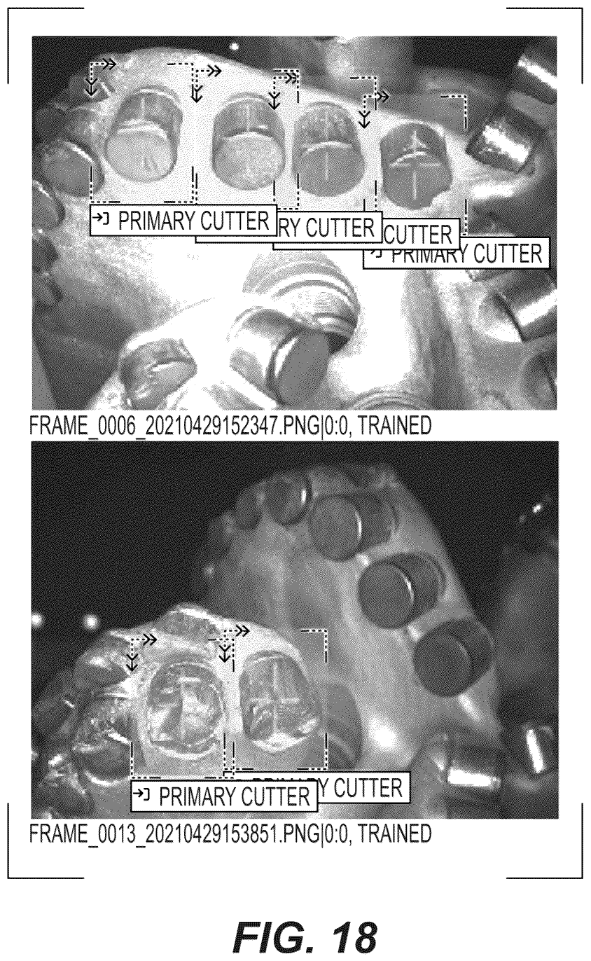

In step 1325, a discrete part of interest is located within an image captured in a scan in step 1320. The part of interest, for example, can be a region corresponding to a cutting element desired to be classified for wear. FIG. 18 shows two example images output by wear classifier tool 1210 that show locations of cutting elements (i.e., primary cutters) found by tool 1210 in step 1325. The cutting elements are disposed in a substrate. The image on the top half in FIG. 18 shows regions of an image that corresponds to four primary cutter elements. The image on the bottom half in FIG. 18 shows regions of an image that corresponds to two primary cutter elements.

In step 1330, one or more failure modes sustained by the used well tool are classified using the trained neural network and the captured wear input data. For example, wear classifier tool 1210 (FIG. 12) can call ML engine 1230 (FIG. 12) to classify a failure mode using the trained ML model 1232 (FIG. 12) and the captured wear input data stored in database 1220 (FIG. 12) or other memory for input to the ML engine 1230. ML engine 1230 applies the input data to the trained ML model 1232 and obtains output data representative of a classification of a failure mode for the captured wear input data.

In step 1340, classified failure mode data is output. For example, wear classifier tool 1210 receives the output data from ML engine 1230 and outputs classified failure mode data for display, storage, or transmission. For example, wear classifier tool 1210 can output for display an image of the scanned used well tool along with the associated classification failure mode data. Wear classifier tool 1210 can also include an alert generator to generate an alert for a user for certain types of failure modes. As shown in an embodiment in FIG. 14, ML engine 1230 includes an inference stage 1410, a training stage 1420, and a neural network 1430. During training step 1310 (FIG. 13), training stage 1420 receives training dataset 1235 and applies it to neural network 1430 to obtain a set of candidate ML models. Training stage 1420 then selects a ML model from the set of candidate ML models for output as the trained ML model 1232. One or more parameters or features 1407 and weights 1409 may also be applied to training stage 1420. For example, training stage 1420 may select the model from the set of candidate ML models which minimizes a loss function using weights 1409 and parameters 1407. Neural network 1430 can be a convolutional neural network (CNN) such as a multi-layer CNN having feature detection and classification. A multi-layer CNN may include a number of convolution layers preceding sub-sampling (pooling) layers coupled to ending layers made up of fully connected (FC) layers.

Training stage 1420 can select a trained multi-layer CNN and associated weights 1409 which minimize a loss function or obtain other optimization. Supervised learning or unsupervised learning with the multi-layer CNN can be used in the training. Parameters or features 1407 and one or more weights 1409 can also be applied during training to the training stage 1420.

Inference stage 1410 receives input data 1405 and applies trained model ML 1232 to determine output data 1440. Parameters or features 1407 and one or more weights 1409 can also be applied during to the inference engine 1410 to further tailor the operation of inference stage 1410. In embodiments, ML engine 1230 applies deep learning. During training to obtain trained ML model 1232, parameters are determined based on characteristics of the training data learned or obtained during the training process rather than a predetermined rule and predetermined parameter based training. Weights based on frequency and/or chronology, e.g. most recent and frequently observed failure modes receive higher weight, may also be learned within deep learning training.

In operation in step 1330, wear data captured in step 1320 can be used as input data 1405. One or more scanned image files of a drill bit in a used well tool can be used. In another example, other data can also be input to inference engine 1430 along with scanned image files to further classification such as image type (2D or 3D), scanner type, sensor information, distance to wear surface, or wear tool information, such as, age, number of cutting elements, and cutting element arrangement or pattern.

Inference stage 1410 applies the trained ML model 1232 to the input data 1405. Trained ML model 1232 extracts features and classifies the input data 1405 to obtain an output array of data. For example, the trained ML model can have a trained multi-layer CNN that applies kernels to input image classification. The output array of data from the multi-layer CNN represents a failure mode.

Parameters 1407 can include additional data pertinent to feature extraction and classification. Parameters 1407 can be used such as, 2D or 3D image type, distance to a captured wear tool surface, or radial position of image. Weights 1409 can be applied to the trained ML model 1232 to further govern inference operation.

Output data 1440 can be an output array of data representative of a classification of a failure mode for the captured wear input data 1405. For example, as shown in FIG. 15, the output array of data can include data identifying one or more cutter failure modes for cutting elements in the drill bit. These types of failure modes can include BC—Broken Cutter, ND—No Damage, WC—Worn Cutter, CD—Chamfer Damage, SC—Spalled Cutter, CC—Chipped Cutter, AB—Axial Break, or TB—Tangential Break. In addition, failure modes could be isolated to the tungsten carbide substrate portion of the PDC cutter to include failure modes erosion, corrosion, rubbing and heat checking. These failure modes are illustrative and not intended to be limiting. Other types of failure modes can be classified depending upon a particular application, tool, and wear being inspected.

In at least one aspect, a method for classifying wear data on a well tool involves training a neural network stored on a computer system at a machine learning engine to categorize common failure modes sustained by used well tools during operation. The training includes inputting an input dataset containing a plurality of known failure mode images and comparing the input dataset to an output generated using the neural network. The method further includes scanning a used well tool with a plurality of scanners in communication with the computer system, thereby generating a scanned file of the used well tool. The scanned file is aligned with a reference surface based on a normalized coordinate format. Finally, the method includes generating one or more failure modes sustained by the used well tool by applying the neural network to the scanned file at the machine learning engine.

As used herein, the term “machine learning” can refer to an application of artificial intelligence technologies to automatically and/or autonomously learn and/or improve from an experience (e.g., training data) without explicit programming of the lesson learned and/or improved upon. Machine learning as used herein can include, but is not limited to, deep learning techniques. Various system components described herein can utilize machine learning (e.g., via supervised, unsupervised, and/or reinforcement learning techniques) to perform tasks such as classification, regression, and/or clustering. Execution of machine learning tasks can be facilitated by one or more machine learning models trained on one or more training datasets in accordance with one or more model configuration settings.

As used herein, the term “machine learning model” can refer to a computer model used to facilitate one or more machine learning tasks (e.g., regression and/or classification tasks). For example, a machine learning model can represent relationships (e.g., causal or correlation relationships) between parameters and/or outcomes within the context of a specified domain. For instance, machine learning models can represent the relationships via probabilistic determinations that can be adjusted, updated, and/or redefined based on historic data and/or previous executions of a machine learning task. In various embodiments described herein, machine learning models can simulate a number of interconnected processing units that can resemble abstract versions of neurons. For example, the processing units can be arranged in a plurality of layers (e.g., one or more input layers, hidden layers, and/or output layers) connected by varying connection strengths (e.g., which can be commonly referred to within the art as “weights”).

Machine learning models can learn through training with one or more training datasets; where data with known outcomes in inputted into the machine learning model, outputs regarding the data are compared to the known outcomes, and/or the weights of the machine learning model are autonomously adjusted based on the comparison to replicate the known outcomes. As the one or more machine learning models train (e.g., utilize more training data), the machine learning models can become increasingly accurate; thus, trained machine learning models can accurately analyze data with unknown outcomes, based on lessons learned from training data and/or previous executions, to facilitate one or more machine learning tasks.

Example types of machine learning models can include, but are not limited to: artificial neural network (“ANN”) models, perceptron (“P”) models, feed forward (“FF”) models, radial basis network (“RBF”) models, deep feed forward (“DFF”) models, recurrent neural network (“RNN”) models, long/short memory (“LSTM”) models, gated recurrent unit (“GRU”) models, auto encoder (“AE”) models, variational AE (“VAE”) models, denoising AE (“DAE”) models, sparse AE (“SAE”) models, markov chain (“MC”) models, Hopfield network (“HN”) models, Boltzmann machine (“BM”) models, deep belief network (“DBN”) models, convolutional neural network (“CNN”) models, deep convolutional network (“DCN”) models, deconvolutional network (“DN”) models, deep convolutional inverse graphics network (“DCIGN”) models, generative adversarial network (“GAN”) models, liquid state machine (“LSM”) models, extreme learning machine (“ELM”) models, echo state network (“ESN”) models, deep residual network (“DRN”) models, kohonen network (“KN”) models, support vector machine (“SVM”) models, and/or neural turing machine (“NTM”) models.

Moreover, various embodiments described herein can constitute one or more technical improvements over conventional oil well tool inspection operations by enhancing the precision and efficiency of damage analysis through the use of dense stereo photogrammetry to create detailed, textured and non-textured 3D models. Additionally, one or more embodiments described herein can have a practical application by training machine learning models to perform the inspection and analysis operations in accordance with defined oil and gas industry objectives. For example, one or more embodiments described herein can reduce cycle times and eliminate the need for additional physical imaging. For instance, the machine learning engine can be executed to render and capture targeted 2D images from the 3D model instantaneously for precise damage analysis. Thereby, the inspection engine can integrate with downstream automated metrology to compare the newly generated 3D model of the used tool with the 3D model of the equivalent new tool in any format, enhancing the overall inspection process.

In further embodiments, output classification modes from inference stage 1410 also include patterns of wear among cutting elements and their relative position on a drill bit and predictive information on whether a drill bit of a well tool needs to be repaired or replaced.

Further examples of training data, input and output data and labels, and parameters and weights and classifications are described below.

### Further Examples and Use Cases

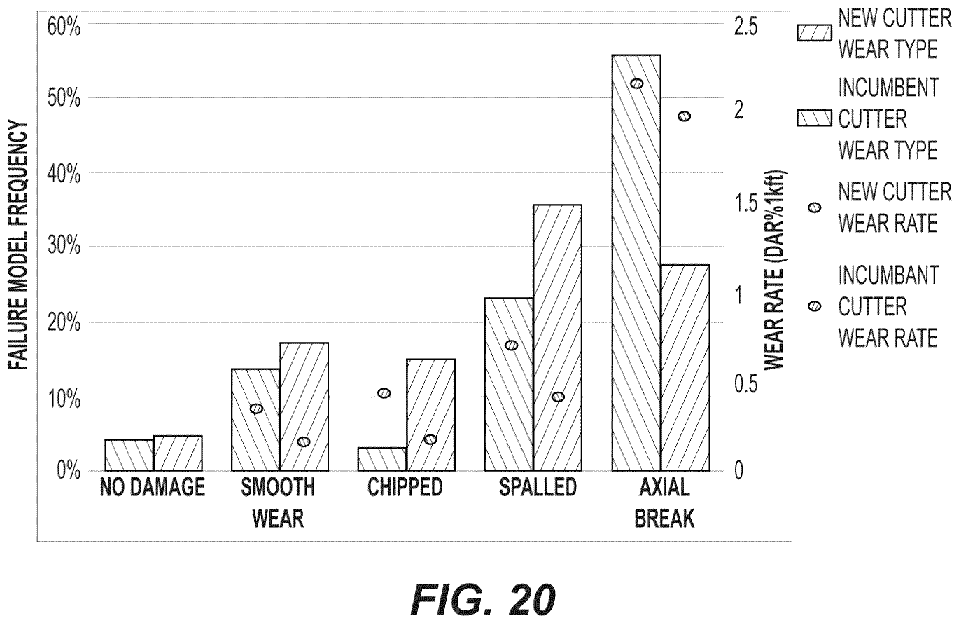

FIG. 20 is graph that shows results of an example case study for new and incumbent cutters tested in a drill bit analyzed by wear classifier tool 1210 according to an embodiment. In this case study, output data was obtained from system 1200 using example 3D scanning metrology and 2D ML models to evaluate failure mode frequency and wear rate for different new and incumbent cutters tested in drill bits. The graph in FIG. 20 shows different wear types determined for new and incumbent cutters plotted along the horizontal axis with failure mode frequency for wear type (shown on the left vertical axis) and wear rate (diamond area removed (DAR) %/footage drilled, shown on the right vertical axis).

The scanner assembly of FIG. 17 is illustrative and not intended to be limiting. Other configurations may be used to scan a well tool for wear. For example, in an embodiment, camera 1702 and 3D scanner 1712 may be attached to the same robotic arm 1704 to obtain data in parallel or in series. Furthermore, the acquisition of data by camera 1702 and/or 3D scanner 1712 could be accomplished manually, without the need for a robotic arm.

### Substrate Damage Classification

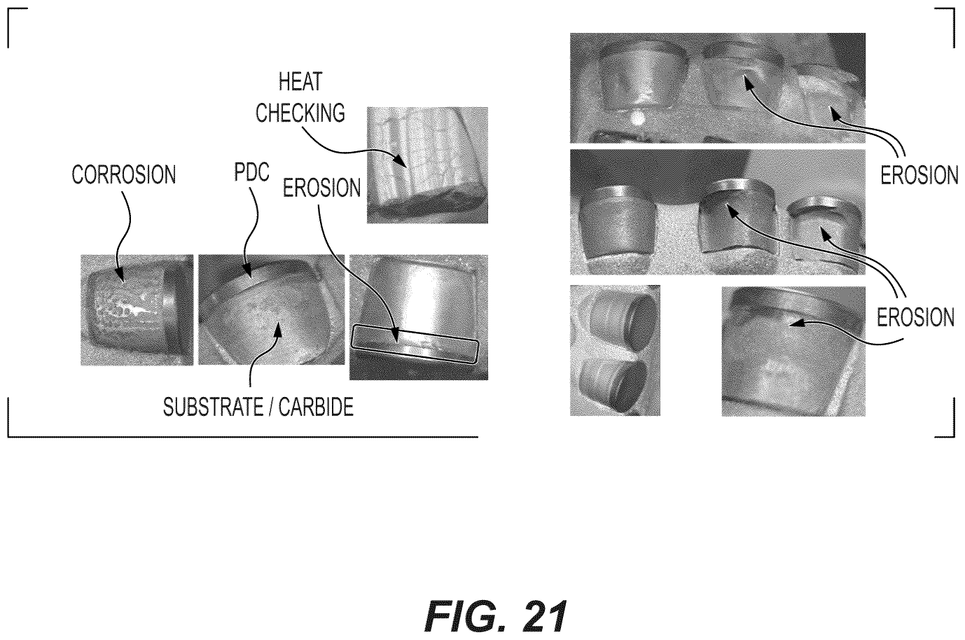

In a further embodiment, wear classifier system 1200 may be further configured to classify different types of substrate damage. Examples of FIG. 21 shows images of different types of substrate damage that may be classified by a wear classification tool. As shown in FIG. 21, types of substrate damage that may be classified include heat checking damage, corrosion, and erosion of the substrate.

In an embodiment, 2D image data and/or 3D scanner data can be used to train a neural network (NN) to identify erosion and corrosion on a PDC cutter substrate. For example, individual cutting elements such as PDC cutters can be separated into two main components, PDC diamond table and tungsten carbide substrate. 2D image data and/or 3D scanner data suitable for identifying erosion and corrosion on a PDC cutter substrate can be used in training dataset 1235.

Wear classifier tool 1210 can then be further configured to use ML engine 1230 (i.e., training stage 1420) train another NN to obtain a further trained ML model 1232 that can be used to identify erosion and corrosion on a PDC cutter substrate. After training is complete, ML engine 1230 can be further configured to receive input data 1405 made up of 2D image data and/or 3D scanner data of drill bit 100 captured by camera 1702 and 3D scanner 1712. ML engine 1230 can then use an inference engine 1410 to process the input data 1405 using training dataset 1235 to identify erosion and corrosion on a PDC cutter substrate.

In a further embodiment, machine learning is used in step 302 to automate the identification of a particular well tool on a stand 206, 1706 or 1716. 2D image data and/or 3D scanner data suitable for identifying a particular well tool (such as a rotary drill bit) can be used in training dataset 1235. For example, wear classifier tool 1210 can be further configured to use ML engine 1230 (i.e., training stage 1420) train another NN to obtain a further trained ML model 1232 that can be used to identify a particular well tool. After training is complete, ML engine 1230 can be further configured to receive input data 1405 made up of 2D image data and/or 3D scanner data of drill bit 100 captured by camera 1702 and 3D scanner 1712. ML engine 1230 can then use an inference engine 1410 to process the input data 1405 using training dataset 1235 to identify a particular drill bit 100 on a stand 206, 1706 or 1716.

### Example Computer-Implemented Embodiments

In embodiments, system 1200 (including its components 1210-1235) can be implemented on one or more computing devices, such as computing system 204. The computing devices may be at the same or different locations. A computing device can be any type of device having one or more processors and memory. For example, a computing device can be a workstation, mobile device (e.g., a mobile phone, personal digital assistant, tablet or laptop), computer, server, computer cluster, server farm, game console, set-top box, kiosk, embedded system, or other device having at least one processor and computer-readable memory. In addition to at least one processor and memory, such a computing device may include software, firmware, hardware, or a combination thereof. Software may include one or more applications and an operating system. Hardware can include, but is not limited to, a processor, memory and user interface display or other input/output device.

Aspects of computing embodiments may also include client and server sides (including remote users on remote computing devices coupled to system 1200) may be implemented electronically using hardware, software modules, firmware, tangible computer readable or computer usable storage media having instructions stored thereon, or a combination thereof and may be implemented in one or more computer systems or other processing systems.

FIG. 24 depicts a schematic flow diagram of an example method 2400 for dense stereo photogrammetry and machine learning. Dense stereo photogrammetry is a technique that uses multiple camera images taken from different angles to create highly detailed and textured 3D models of objects or environments. By analyzing the disparities between the images, this method generates precise depth information, enabling accurate reconstruction of the object's surface geometry. The method 2400 may be implemented by the system 200, the system 1200, and/or the system 2500 (see FIG. 25) and may utilize any of the features described in further detail above. The method 2400 may further be implemented alone or in combination with any portion of method 300 of FIG. 3 and/or method 1300 of FIG. 13.

The method 2400 may begin at step 2402 by pretreating a tool targeted for analysis (e.g., drill bit 100 of FIG. 1). In at least one embodiment, step 2402 may include initial preparation of the tool, including cleaning of the tool and/or surface treatment of the tool. Method 2400 continues to step 2404, which includes staging an object for analysis. The object may be the tool of step 2402 (e.g., the drill bit 100), or a portion of the tool (e.g., a discrete wear part, a part of interest, etc.). In at least one embodiment, the object may be placed on a support structure (e.g., support structure 208, support structure 2506 of FIG. 25) to ensure that the object is positioned in a specific orientation consistent for accurate scanning, and alignment of subsequently generated models.

At step 2406, the object may be defined within a computer system. In at least one embodiment, defining the object includes inputting relevant data and/or metadata about a tool (e.g., part number, serial number, and the like). In at least one embodiment, a user may input data manually to define an object. In at least one embodiment, input data may be pre-loaded from the computer system. After the object is defined, the method 2400 may proceed to step 2408 by scanning the object. In at least one embodiment, the scanning may include using an array of cameras (e.g., scanners 2502a-d of FIG. 25) to capture detailed images of the tool from multiple angles. In one example, the scanned images of the object may be defined according to and/or aligned with a normalized coordinate format, such as the normalized coordinate format described with respect to FIG. 23. The normalized coordinate system may be generated based in part on dimensional information associated with the used well tool, such as predefined dimensional information, pre-scanned dimensional information, specified dimensional information, and the like. In at least one embodiment, defining the scanned images according to a normalized coordinate system may include scanning the tool alongside a set of targets surrounding the tool, the targets providing reference points for aligning the scanned images with a normalized coordinate system.

In some embodiments, aligning the scanned images with the normalized coordinate system includes defining a reference surface within the normalized coordinate system. The reference surface may be a 2D or 3D surface defined according to one or more points within the normalized coordinate system. The one or more points may be pre-defined based on pre-specified dimensional information regarding the well tool, pre-scanned dimensional information regarding the well tool, or may be defined using any other suitable dimensional information. Such dimensional information may be user-defined, and/or auto generated using techniques such as machine learning. The reference surface may be derived from a 3D solid model (e.g., a CAD model), a mesh, or may be defined independent from any 2D or 3D representation of the well-tool. The reference surface may include any point, plane, or polygon against which the scanned images of the well tool may be compared and/or measured. Alignment of the scanned images with the reference surface may include a computer system (e.g., system 204 and/or system 2504) defining corresponding points between the scanned images and the normalized coordinate system by evaluating the scanned images and the normalized coordinate system for mutual information. Corresponding points may be aligned such that the scanned images may be measured against the normalized coordinate system.

In at least one embodiment, the relocated models may be models approved after inspection at step 2412 and deemed suitable for further analysis. The target database may be capable of performing further analysis, such as machine learning analysis that is described in greater detail above. In at least one embodiment, relocating the models may include reorganizing or reordering models within a single database.

The method 2400 may proceed to optional step 2416 by generating parts of interest (POI) coordinates from the approved models. In at least one embodiment, POIs may be individual (discrete) wear parts, such as the wear parts described in greater detail above. In at least one embodiment, design models or select points on the models may be used to generate coordinates for specific POIs on the tool. In one example, coordinates for specific POIs may be normalized according to a normalized coordinate format, such as the normalized coordinate format described with respect to FIG. 23. In at least one embodiment, POI coordinates may be generated from design files, independent of the approved model.

The method 2400 may proceed to step 2418 by aligning coordinates (e.g., for POIs) with coordinate matrices associated with the textured 3D models processed during steps 2410-2414. Alignment may be normalized and expedited where a normalized coordinate system is implemented. At step 2420, images (e.g., of the POIs) may be captured (e.g., by scanners 2502a-d of FIG. 25) at specified coordinates. In at least one embodiment, specified coordinates may be manually selected or automatically selected based on one or more criteria. In at least one embodiment, the captured images target targeted offsets and targeted angles.

The method 2400 may proceed to step 2422 by applying machine learning techniques to images captured during step 2420 to classify any damage that may be present on the tool. In at least one embodiment, the machine learning techniques may include at least one of supervised learning techniques, unsupervised learning techniques, semi-supervised learning techniques, and reinforcement learning techniques. For example, the machine learning techniques may include any portion of the machine learning techniques described with respect to at least FIGS. 12 and 13. The machine learning techniques may be integrated with any features described in detail above.

FIG. 25 is a schematic diagram of an example scanning system 2500 that may incorporate the principles of the present disclosure. The scanning system 2500 (hereafter “the system 2500”) may be configured to scan a well tool, such as the drill bit 100 (FIG. 1). As illustrated, the scanning system 2500 includes a plurality of scanners 2502a, 2502b, 2502c, 2502d (e.g. cameras) and a computer system 2504 in communication with the scanners 2502a-d. In some embodiments, the computer system 2504 may include two or more devices (e.g., multi-pc workflow, virtual-or cloud-based architectures) networked together or otherwise capable of communicating one with the other. Having more than one device may be advantageous in increasing capacity (e.g., maximizing number of well tools scanned without delay due to inspection) while creating real-time/simultaneous inspections upon completion of a scan. In one non-limiting example, the computer system 2504 may include a scanning computer separate from an inspection computer, any architecture of computational services, microservices, managed/hosted services, and dedicated computational servers, among other computer devices. In one non-limiting example, the computer system 2504 may include a cloud-based scanning device separate from a cloud-based inspection device, among other computer devices.

In some embodiments, the stand 2506 may be automated, but may alternatively be manually operated. In such embodiments, the scanners 2502a-d may remain stationary and the stand 2506 may be rotatable and/or movable up and down to help enable adequate scanning of the drill bit 100. In at least one embodiment, for example, the stand 2506 may comprise a rotary table or the like. In some embodiments, one or more targets 2508 may be disposed at (e.g., situated on and/or inlayed at) the stand 2506 to facilitate triangulation procedures associated with defining and refining the normalized coordinate system. The targets 2508 may be configured in any configuration suitable for triangulation procedures, such as the planetary configuration of four targets 2508 as illustrated in FIG. 25, though other target configurations are contemplated. In some embodiments, the targets 2508 may be affixed to the drill bit 100 during a scanning procedure.

In other embodiments, the scanners 2502a-d may be movable while the stand 2506 and the drill bit 100 remain stationary. For example, in at least one embodiment, the scanners 2502a-d may be mounted to a rotatable apparatus or movable system configured to move about the periphery of the stand 2506. In other embodiments, the scanners 2502a-d may comprise a hand-held scanning system and a user or operator may hold one or more of the scanners 2502a-d and walk around the periphery of the drill bit 100 while digitally “painting” the drill bit 100 with the scanners 2502a-d to obtain the necessary scanned images (3D or 2D). In some embodiments, the stand 2506 may be mounted over and/or adjacent to a backdrop structure (not shown) configured to eliminate background images or “noise”. In some embodiments, the system 2504 may be disposed below the backdrop structure (not shown).

In some embodiments, the scanners 2502a-d may be designed to obtain high-resolution two-dimensional (2D) images of the drill bit 100, without departing from the scope of the disclosure. In such embodiments, the scanners 2502a-d may comprise high-resolution cameras or the like capable of obtaining high-resolution 2D photographic (still) images and/or video. In one example, scanners 2502a-d may obtain about 150 images or more to 500 images or less (e.g., 250 images to 400 images) during a single rotation of the drill bit 100 about an axis (e.g., axis 108 of FIG. 1) of the stand 2506, though other values are contemplated. Moreover, in such embodiments, the computer system 204 may be programmed or otherwise configured to implement photogrammetry techniques to gather measurements and data about the well tool by analyzing the change in angle and/or position from two or more different images. Accordingly, the principles of the present disclosure are equally applicable to 2D scanning operations.

In one embodiment, dense stereo photogrammetry may be used to generate the model on a computer system (e.g., the system 202 and/or the system 2504 of FIG. 25). The model may be generated from the 150 to 500 images obtained during the scan. The images may be overlapping, and may be evaluated within the system to identify certain features (e.g., features of the scanned part and/or targets on the well tool). The certain features may be used to find pixels within each of the generated images that correspond with one another. By identifying corresponding pixels, the system may produce a dense set of matched points. Once features are identified using the matched points, triangulation may be used to determine, e.g., by way of geometric processing, 3D coordinates for each matched point. All images, matched features, matched points, and corresponding 3D coordinates are used to generate a dense point cloud that can then be converted into a 3D mesh (e.g., a mesh including connecting the dots to form a continuous surface) that represents the physical geometric surface of the object, as discussed in further detail below.

In some embodiments, the scanners 2502a-d may be mounted to a support assembly 2514 capable of positioning the scanners 2502a-d to face the drill bit 100 at various angles about the drill bit 100 to capture scanned images (3D or 2D) of all exterior portions of the drill bit 100. In one such embodiment, scanners 2502a and 2502b may be positioned substantially above the vertical height of the drill bit 100, and scanners 2502c and 2502d may be positioned substantially below the vertical height of the drill bit 100. Moreover, in at least one embodiment, scanners 2502a and 2502c may be aligned in a common vertical plane, and scanners 2502b and 2502d may be aligned in a common vertical plane.

In some embodiments, the drill bit 100 may be prepared for scanning, such as by applying reflective markers to assist in stitching the 3D scan together, applying matting spray to remove reflective glare, and the like. The scanner 202 may be designed to operate with an accuracy of approximately 0.0005-0.003 inches or better. In some embodiments, lighting structures 2512 may be mounted to the support assembly and positioned at various angles relative to the drill bit 100 (e.g., in a planetary configuration) to enhance the reflection during 2D and 3D scanning.

The scanners 2502a-d may communicate with the computer system 2504 via any known wired or wireless means. In at least one embodiment, the computer system 2504 may comprise one component of a larger computer network. The computer system 2504 may include one or more processors (e.g., one or more central processing units (CPUs), the processors operating in parallel and/or operating in sequence) and a non-transitory, computer readable medium (i.e., a memory) programmed with computer-executable instructions that, when executed by the processor, perform the methods described herein. More particularly, the computer system 2504 may have 3D modeling and metrology software stored thereon, or may be otherwise connected to a device with 3D modeling and metrology software stored thereon, which may include instructions to receive and process images captured by the scanners 2502a-d and generate a 3D image of the drill bit 100 based on the captured images.

The 3D image of the drill bit 100 may comprise a scanned “mesh” file (e.g., .stl, point cloud, IGES, STEP, etc.) comprising a complex polygon mesh structure corresponding to the scanned dimensions and configurations of the drill bit 100 as obtained by the scanners 2502a-d. After the mesh is generated, the original images may be used to apply texture to the 3D mesh, wrapping photographic information from the about 150 images or more to 500 images or less (e.g., 250 images to 400 images) onto the mesh. In at least one embodiment, the scanned file of the drill bit 100 may be compared and/or measured against a solid model (e.g., a computer-aided design or CAD solid model) file of the drill bit 100 corresponding to the original manufacturer specifications for the drill bit 100. The scanned file may be spatially aligned with the corresponding solid model file and any deviation between individual scanned parts (regions) and the corresponding solid model parts may be indicative of how much wear the drill bit 100 experienced during operation. Such comparisons may be used to quantify, often in a digital format, specific amounts of abrasion, erosion, and/or wear of associated blades 104 (FIG. 1), cutting elements 110 (FIG. 1), and/or gauge pads 112 (FIG. 1), for example.

In at least one embodiment, the scanned file of the drill bit 100 may be compared and/or measured against a normalized coordinate system associated with the drill bit 100 corresponding to the original manufacturer specifications for the drill bit 100. The scanned file may be spatially aligned with the normalized coordinate system and any deviation between individual scanned parts (regions) and the corresponding normalized coordinate system may be indicative of how much wear the drill bit 100 experienced during operation. Such comparisons may be used to quantify, often in a digital format, specific amounts of abrasion, erosion, and/or wear of associated blades 104 (FIG. 1), cutting elements 110 (FIG. 1), and/or gauge pads 112 (FIG. 1), for example.

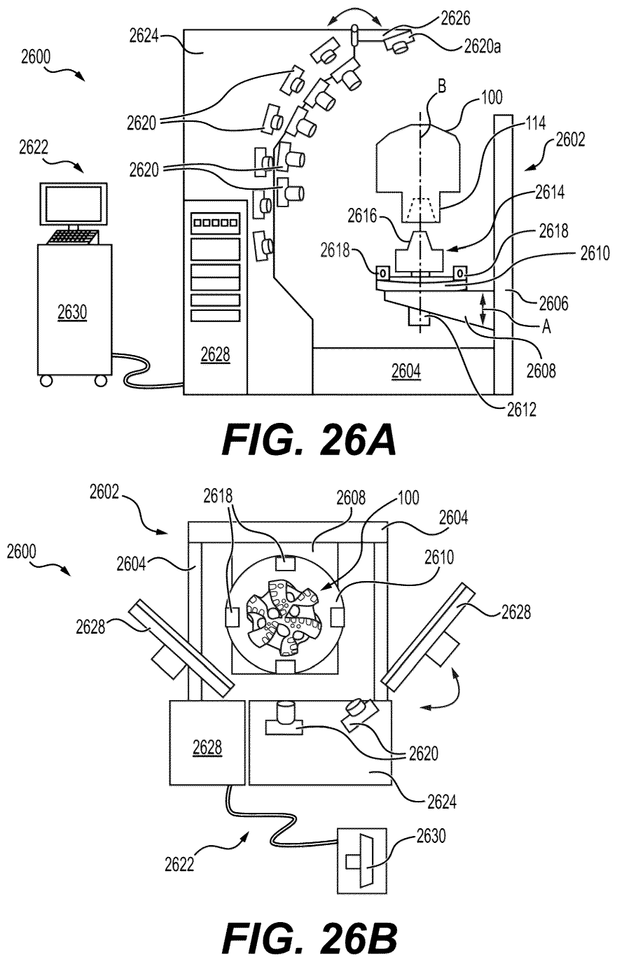

FIGS. 26A and 26B are schematic front and plan views of another example scanning system 2600 in accordance with the principles of the present disclosure. The scanning system 2600 (hereafter “the system 2600”) may be similar in some respects to the system 2500 of FIG. 25 and therefore may be best understood with reference thereto. Similar to the system 2500, the system 2600 is configured to scan a well tool, such as the drill bit 100.

In the illustrated embodiment, the drill bit 100 is mountable to a stand 2602. The stand 2602 may include a base 2604, a support column 2606 attached to and extending vertically from the base 2604, and an arm 2608 extending laterally from the support column 2606. The arm 2608 may be able to vertically traverse (e.g., move up and down) the support column 2606, as indicated by the double-ended arrow A, thereby positioning the drill bit 100 at desired elevations. A turntable 2610 is rotatably mounted to the arm 2608 and is actuatable to rotate about an axis B using one or more motors or servos 2612 (FIG. 26A) operatively coupled to the turntable 2610.

In some embodiments, as illustrated, a centering cone 2614 (FIG. 26A) may be removably mounted to the turntable 2610 and configured to receive the drill bit 100. The centering cone 2614 defines a conical member 2616 sized to be received within the pin 114 of the drill bit 100. To accommodate for differing sizes of the drill bit 100, the centering cone 2614 may be removed and replaced with an appropriately sized centering cone configured to receive the drill bit 100. The drill bit 100 may be lowered onto the centering cone 2614 using a crane or the like, and once properly mounted to the centering cone 2614, the drill bit 100 is rotatable about the axis B as the turntable 2610 rotates.

In some embodiments, one or more targets 2618 may be arranged on the stand 2602, such as being mounted to the turntable 2608, to facilitate triangulation procedures associated with defining and refining a normalized coordinate system. The targets 2618 may be configured in any configuration suitable for triangulation procedures, such as the planetary configuration of four targets 2618 as illustrated in FIG. 26B, though other target configurations are contemplated.

The system 2600 includes a plurality of scanners 2620 (e.g., cameras) and a computer system 2622 in communication with the scanners 2620. The scanners 2620 may be mounted to a support assembly 2624, which may be operatively coupled to the base 2604 (FIG. 26A). In other applications, however, the support assembly 2624 may be freestanding and otherwise movable relative to the stand 2602. In the illustrated embodiment, the scanners 2620 are fixed to the support assembly 2624 and, as best seen in FIG. 26B, may be arranged in two laterally offset columns. In at least one embodiment, as best seen in FIG. 26A, at least one of the scanners 2620, shown as scanner 2620a, may be mounted to a movable (actuatable) swing arm 2626 pivotably mounted to the support assembly 2624. The swing arm 2626 may be retracted and otherwise moved out of the path of the drill bit 100 as it is lowered vertically onto the centering cone 2614. Once the drill bit 100 is properly mounted to the centering cone 2614, the swing arm 2626 can be pivoted back, thereby arranging the additional scanner 2620a back into position to obtain images of the drill bit 100.

In some embodiments, as best seen in FIG. 26B, the system 2600 further includes one or more lighting panels or structures 2628 (two shown) mounted to the support assembly 2624. The lighting structures 2628 may be movable and otherwise actuatable to be positioned at various angles relative to the drill bit 100 (e.g., in a planetary configuration). As will be appreciated, the lighting structures 2628 will help enhance image quality and reflection during 2D and 3D scanning.

The support assembly 2624 may be capable of positioning the scanners 2620 to face the drill bit 100 at various angles to thereby capture scanned images (3D or 2D) of all exterior portions of the drill bit 100. For example, one or more scanners 2620 may be positioned substantially above the vertical height of the drill bit 100, one or more additional scanners 2620 may be positioned substantially below the vertical height of the drill bit 100, and one or more additional scanners 2620 may be aligned in a common vertical plane (height) with the drill bit 100.

The scanners 2620 are designed to obtain high-resolution two-dimensional (2D) or three-dimensional (3D) images of the drill bit 100, and may thus comprise high-resolution cameras capable of obtaining high-resolution 2D or 3D photographic (still) images and/or video. The scanners 2620 may be able to obtain between 150 and 500 images during a single rotation of the drill bit 100 about the axis B. The computer system 2622 is in communication with the scanners 2620 to receive and process the images obtained by the scanners 2620. As illustrated, the computer system 2622 can include at least an electronics rack 2628 and an operator kiosk 2630 in communication with the electronics rack 2628.

The computer system 2622 may be programmed or otherwise configured to implement photogrammetry techniques to gather measurements and data about the drill bit 100 by analyzing the change in angle and/or position from two or more different images. Similar to the computer system 2504 of FIG. 25, the computer system 2622 may be configured to implement dense stereo photogrammetry to generate the model. Operation of the computer system 2622 may be the same as or similar to the computer system 2504 and, therefore, will not be described again in detail.

Implementation of the systems and methods provided herein may offer a multitude of advantages. These advantages include a rapid cycle time, as the system can acquire hundreds of images within one rotation of the tool or cameras and virtually capture images almost instantaneously, thereby streamlining the inspection process and enhancing productivity. The system also offers operational flexibility, adapting to various tool sizes and optimizing imaging conditions through adjustable camera or tool movement. Precision is another key advantage, achieved by generating a comprehensive 3D model with minimal moving parts, which ensures maximum reproducibility and repeatability of downstream measurement and analysis while eliminating the need for additional physical imaging. Operational efficiency is significantly enhanced by using a single system that requires only one rotation of the tool to produce both a textured 3D model and targeted 2D renderings for downstream metrology and computer vision analysis. Storage efficiency is improved by generating a single textured 3D model from which 2D renderings can be ephemerally generated at the time of analysis, thus avoiding the need for persistent storage of large image files. The system's maintainability benefits from having minimal moving parts, and its physical scalability is enhanced by the portability of the single system. Digital scalability is achieved through minimal configuration and inputs, allowing for real-time generation of a single output 3D model from which all derivations can be produced. Finally, the system's accuracy, maintainability, and scalability are further improved by leveraging configurable points of interest derived from manufacturing specifications, ensuring superior repeatability, accuracy, and reproducibility of inspection data compared to machine learning-based segmentation approaches.

Therefore, the disclosed systems and methods are well adapted to attain the ends and advantages mentioned as well as those that are inherent therein. The particular embodiments disclosed above are illustrative only, as the teachings of the present disclosure may be modified and practiced in different but equivalent manners apparent to those skilled in the art having the benefit of the teachings herein. Furthermore, no limitations are intended to the details of construction or design herein shown, other than as described in the claims below. It is therefore evident that the particular illustrative embodiments disclosed above may be altered, combined, or modified and all such variations are considered within the scope of the present disclosure. The systems and methods illustratively disclosed herein may suitably be practiced in the absence of any element that is not specifically disclosed herein and/or any optional element disclosed herein. While compositions and methods are described in terms of “comprising,” “containing,” or “including” various components or steps, the compositions and methods can also “consist essentially of” or “consist of” the various components and steps. All numbers and ranges disclosed above may vary by some amount. Whenever a numerical range with a lower limit and an upper limit is disclosed, any number and any included range falling within the range is specifically disclosed. In particular, every range of values (of the form, “from about a to about b,” or, equivalently, “from approximately a to b,” or, equivalently, “from approximately a-b”) disclosed herein is to be understood to set forth every number and range encompassed within the broader range of values. Also, the terms in the claims have their plain, ordinary meaning unless otherwise explicitly and clearly defined by the patentee. Moreover, the indefinite articles “a” or “an,” as used in the claims, are defined herein to mean one or more than one of the elements that it introduces. If there is any conflict in the usages of a word or term in this specification and one or more patent or other documents that may be incorporated herein by reference, the definitions that are consistent with this specification should be adopted.

As used herein, the phrase “at least one of” preceding a series of items, with the terms “and” or “or” to separate any of the items, modifies the list as a whole, rather than each member of the list (i.e., each item). The phrase “at least one of” allows a meaning that includes at least one of any one of the items, and/or at least one of any combination of the items, and/or at least one of each of the items. By way of example, the phrases “at least one of A, B, and C” or “at least one of A, B, or C” each refer to only A, only B, or only C; any combination of A, B, and C; and/or at least one of each of A, B, and C.

What is claimed is:

1. A method of quantifying wear data on a well tool, comprising:
scanning a used well tool with one or more scanners and thereby generating a scanned file of the used well tool, the one or more scanners being in communication with a computer system;
generating a normalized coordinate format at the computer system, based in part on dimensional information associated with the used well tool;
aligning the scanned file with a reference surface of the used well tool using the normalized coordinate format, wherein the reference surface is defined using a set of points within the normalized coordinate format, and is stored on the computer system; and
calculating deviation between the scanned file and the reference surface and thereby determining material removed from individual wear parts of the used well tool.

2. The method of claim 1, further comprising identifying the used well tool based on an original model file and one or more data files corresponding to the used well tool,
wherein the original model and the one or more data files comprise design and preparation files stored on the computer system and corresponding to an original manufacturer specification for the used well tool, and
wherein the original model and data files are separable into the individual wear parts of the well tool to identify the individual wear parts.

3. The method of claim 2, wherein the design and preparation files comprise at least one of computer-aided design (CAD) files, mesh files, object-like files, user input files, comma-separated value files, JavaScript Object Notation (JSON) files, YAML Ain't Markup Language (YAML) files, Tom's Obvious Minimal Language (TOML) files, stereolithography (STL) files, Standard for the Exchange of Product (STP) files, Initial Graphics Exchange Specification (IGS) files, polygon file format (PLY) files, Extensible Markup Language (XML) files, HyperText Markup Language (HTML) files, and Structured Query Language (SQL) database files.

4. The method of claim 1, wherein aligning the scanned file with the reference surface comprises aligning one or more points of the scanned file with one or more corresponding points of the reference surface of the used well tool based on mutual information between the scanned file and the reference surface, the mutual information based, at least in part, on the normalized coordinate format.

5. The method of claim 1, the method further comprising:
identifying individual wear parts of the used well tool using at least a differential output; and
creating digital features based on the individual wear parts of the scanned file.

6. The method of claim 5, wherein creating the digital features based on the wear parts of the scanned file comprise:
measuring against a defined failure surface on one of the wear parts with a plurality of computer-generated digital features; and
assigning a failure mode to the defined failure surface based on a geometry of the plurality of computer-generated digital features.

7. The method of claim 5, wherein creating a digital feature based on one or more of the individual wear parts comprises:
generating coordinates for the one or more individual wear parts, the coordinates based on the normalized coordinate format; and
based on the coordinates, scanning the one or more individual wear parts with the one or more scanners and thereby generating an individual scanned file for each of the one or more individual wear parts.

8. The method of claim 1, further comprising:
pretreating a surface of the well tool; and
staging the well tool on a support structure, the support structure rotatable to align the one or more individual wear parts with the one or more scanners.

9. The method of claim 1, wherein the normalized coordinate format is recorded in at least one of JavaScript object notation (JSON) files, extensible markup language (XML) files, Extensible Markup Language (HTML), Structured query language (SQL) database files, spreadsheet files, comma-separated value (CSV) files, YAML Ain't Markup Language (YAML) files, Tom's Obvious Minimal Language (TOML) files, stereolithography (STL) files, Standard for the Exchange of Product (STP) files, Initial Graphics Exchange Specification (IGS) files, polygon file format (PLY) files, hierarchical data files, tabular data files, structured data files, semi-structured data files, relational data files, or any combination herein.

10. The method of claim 1, wherein the reference surface is derived from at least one of a three-dimensional model and a two-dimensional model.

11. A system, comprising:
a training engine configured to train a neural network to categorize common failure modes sustained by used well tools during operation, wherein training includes:
inputting an input dataset including a plurality of known failure mode images; and
comparing the input dataset to an output generated using the neural network;
one or more scanners configured to scan a used well tool;
a computer system in communication with the one or more scanners and configured to, based on the scanning, generate a scanned file of the used well tool; and
an inference engine in communication with the training engine and the computer system, the inference engine configured to generate one or more failure modes sustained by the used well tool by applying the neural network to the scanned file.

12. The system of claim 11, wherein the training further includes, based on the comparing, adjusting one or more weights of the neural network.

13. The system of claim 11, wherein the scanned file is aligned with a reference surface based on a normalized coordinate format.

14. The system of claim 13, wherein the reference surface is defined using a set of points within the normalized coordinate format.

15. The system of claim 11, wherein both the training engine and the inference engine are at a machine learning engine.

16. A system, comprising:
one or more scanners arrangeable to scan a used well tool; and
a computer system in communication with the one or more scanners and including a non-transitory, computer readable medium programmed with computer executable instructions that, when executed by a processor of the computer system, performs the steps of:
generating a scanned file of the used well tool based on a signal received from the one or more scanners, the scanned file being aligned with a reference surface based on a normalized coordinate format;
generating a normalized coordinate format at the computer system, based in part on dimensional information associated with the used well tool;
aligning the scanned file with a reference surface of the used well tool sing the normalized coordinate format, wherein the reference surface is defined using a set of points within the normalized coordinate format, and is stored on the computer system; and
calculating deviation between the scanned file and the reference surface using and thereby determining material removed from the individual wear parts of the used well tool.

17. The system of claim 16, wherein the computer system is in communication with one or more cameras configured to capture ultra-high-resolution images of the used well tool.
